(19) United States
(12) Patent Application Publication
(10) Pub. No.: US 2026/0033082 A1
(43) Pub. Date: Jan. 29, 2026

(54) DISPLAY APPARATUS

(71) Applicant: LG DISPLAY CO., LTD., Seoul (KR)

(72) Inventors: Hae Sung LEE, Paju-si (KR); Kyoung June JUNG, Paju-si (KR); Dae Han WON, Paju-si (KR)

(73) Assignee: LG DISPLAY CO., LTD., Seoul (KR)

(21) Appl. No.: 19/252,747

(22) Filed: Jun. 27, 2025

(30) Foreign Application Priority Data
Jul. 29, 2024 (KR) 10-2024-0100204

(51) Int. Cl. H10H 29/49; H01L 25/16; H10H 29/37; H10H 29/855

(52) U.S. Cl. CPC H10H 29/49; H01L 25/167; H10H 29/37; H10H 29/855

(57) ABSTRACT

A display apparatus according to one or more examples includes a substrate; a display area, and a non-display area outside the display area; a loopback wire located in the non-display area; and a pad connection wire in the non-display area. The pad connection wire may have a length that is different from the length of the loopback wire.

### CROSS-REFERENCE TO RELATED APPLICATION

This application claims the benefit of and priority to Korean Patent Application No. 10-2024-0100204, filed Jul. 29, 2024, the entire contents of which are incorporated herein by reference for all purposes.

### BACKGROUND

### 1. Technical Field

The present disclosure relates to a display apparatus.

### 2. Discussion of Related Art

Display apparatuses are employed in various electronic devices such as televisions (TV), mobile phones, laptops, and tablets.

A display apparatus includes an organic light emitting display (OLED) that emits light by itself and a liquid crystal display (LCD) that requires a separate light source.

In recent, a display apparatus including a light emitting diode (LED) has attracted attention as a next-generation display apparatus. Since the light-emitting diode is made of inorganic materials rather than organic materials, it has a faster lighting speed, higher emission efficiency, and higher luminance compared to liquid crystal displays and organic light-emitting displays.

The description of related art should not be considered prior art merely because it is mentioned in or associated with this section. The description of related art includes information that describes one or more aspects of the subject technology, and the description in this section does not limit the scope of the invention.

### SUMMARY

An inspection may be required during the production process of a display apparatus to determine whether the display apparatus product is being produced normally. While it is possible to inspect the display apparatuses in the final product state to determine if it has been manufactured normally, it may be advantageous to the yield of a high quality final product to inspect the product at each specific step in the manufacturing process to identify the cause of the defect and reduce the defect before proceeding to the next process.

A problem to be solved according to one or more aspects of the present disclosure is to provide a display apparatus that is capable of reducing defects.

The problems to be solved by an embodiment of the present disclosure is not limited to those mentioned above, and other problems not mentioned will be clearly understood by those skilled in the art from the present disclosure.

A display apparatus according to an embodiment of the present disclosure may include: a substrate; a display area and a non-display area outside the display area; a loopback wire located in the non-display area; and a pad connection wire located in the non-display area and having a length that is different from a length of the loopback wire.

A display apparatus according to an embodiment of the present disclosure may include: a substrate; a display area and a non-display area outside the display area; a first electrode located in each of the display area and the non-display area, and a light-emitting element arranged on the first electrode; a second electrode located in the display area and arranged on the light-emitting element; and a third electrode located in the non-display area and arranged on the dummy light-emitting element, a loopback wire located in the non-display area and connected to the dummy light-emitting element, and a pad connection wire located in the non-display area and connected to the dummy light-emitting element.

Detailed items according to various examples of the present disclosure, other than the configuration described above are included in the following description and the accompanying drawings.

According to one or more aspects of the present disclosure, defects may be reduced during the manufacturing process, thereby improving the yield of the display apparatus.

The effects of the present disclosure are not limited to the effects mentioned above, and other effects not mentioned will be apparent to one having ordinary skill in the art to which the technical ideas of the present disclosure belong from the following description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an exploded perspective view of a display apparatus according to an embodiment of the present disclosure;

FIG. 2 is a plan view of the display apparatus according to an embodiment of the present disclosure;

FIG. 3 is a plan view illustrating the display apparatus according to an embodiment of the present disclosure;

FIG. 4 is a block diagram illustrating the display apparatus according to an embodiment of the present disclosure;

FIGS. 5 to 7 are plan views illustrating the display apparatus according to an embodiment of the present disclosure;

FIG. 8 is a plan view illustrating a display area and a non-display area according to an embodiment of the present disclosure;

FIG. 9 is a plan view illustrating a display area and a non-display area according to an embodiment of the present disclosure;

FIG. 10 is a plan view illustrating the display area and the non-display area according to an embodiment of the present disclosure;

FIG. 11 is an enlarged view illustrating the display apparatus according to an embodiment of the present disclosure;

FIG. 12 is a diagram illustrating a circuit structure according to an embodiment of the present disclosure;

FIG. 13 is a cross-sectional view illustrating the display apparatus according to an embodiment of the present disclosure;

FIG. 14 is a cross-sectional view of the display apparatus according to an embodiment of the present disclosure;

FIG. 15 is a cross-sectional view of the display apparatus according to an embodiment of the present disclosure;

FIG. 16 is a cross-sectional view illustrating the display apparatus according to an embodiment of the present disclosure;

FIG. 17 is a cross-sectional view illustrating the display apparatus according to an embodiment of the present disclosure;

FIG. 18 is a plan view illustrating the display apparatus according to an embodiment of the present disclosure;

FIGS. 19 to 20 are partially enlarged views illustrating an enlarged portion O of FIG. 18;

FIG. 21 is a cross-sectional view illustrating the display apparatus according to an embodiment of the present disclosure;

FIG. 22 is a cross-sectional view illustrating a display apparatus according to another embodiment of the present disclosure;

FIGS. 23 to 30 are views illustrating the display apparatus according to embodiments of the present disclosure;

FIGS. 31 to 35 are plan views illustrating the display apparatus according to an embodiment of the present disclosure; and

FIGS. 36 to 39 are diagrams illustrating an apparatus to which the display apparatus according to embodiments of the present disclosure is applied.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

The advantages and features of the present disclosure, and methods of achieving them will become apparent upon reference to the embodiments described in detail below in conjunction with the accompanying drawings. However, the present disclosure is not limited to the following embodiments disclosed herein, but may be implemented in various different forms; rather, the present embodiments are provided to make the disclosure of the present disclosure complete and to enable those skilled in the art to fully comprehend the scope of the present disclosure.

The shapes, sizes, proportions, angles, numbers, and the like of elements shown in the drawings to illustrate embodiments of the present disclosure are merely illustrative and are not intended to be limiting. Identical reference numerals may designate identical components throughout the description. Further, in describing the present disclosure, detailed descriptions of related known technologies may be omitted so as not to obscure the essence of the present disclosure. The terms such as “including,” “having,” and “comprising” used herein are generally intended to allow other components to be added unless the terms are used with the term “only.” References to components of a singular noun include the plural of that noun, unless specifically stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “following,” “next to,” or “before” describes a temporal antecedent or consequent relationship, which may not be continuous unless “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), or (b) may be used to describe elements of the embodiments of the present disclosure. Such terms are intended only to distinguish one component from another and are not intended to define the nature, sequence, order, or number of such components.

When a component is described as being “connected,” “coupled,” “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contacted” or “overlapped” with another component, it is to be understood that the component may be in direct contacted or overlap with the other component, but that there may also be other components “interposed” between the respective components which may be in direct or indirect contacted or overlap with, unless specifically stated otherwise.

It should be understood that the term “at least one” includes all possible combinations of one or more related components. For example, the meaning of “at least one of the first, second, and third components” can be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present disclosure may function.

Each of the features of various embodiments of the present disclosure may be coupled or combined with one another in whole or in part, and may be technologically interlocked and operated in various ways, and each of the embodiments may be carried out independently or in conjunction with one another.

Hereinafter, various embodiments of the present disclosure will be described in detail with reference to the accompanying drawings.

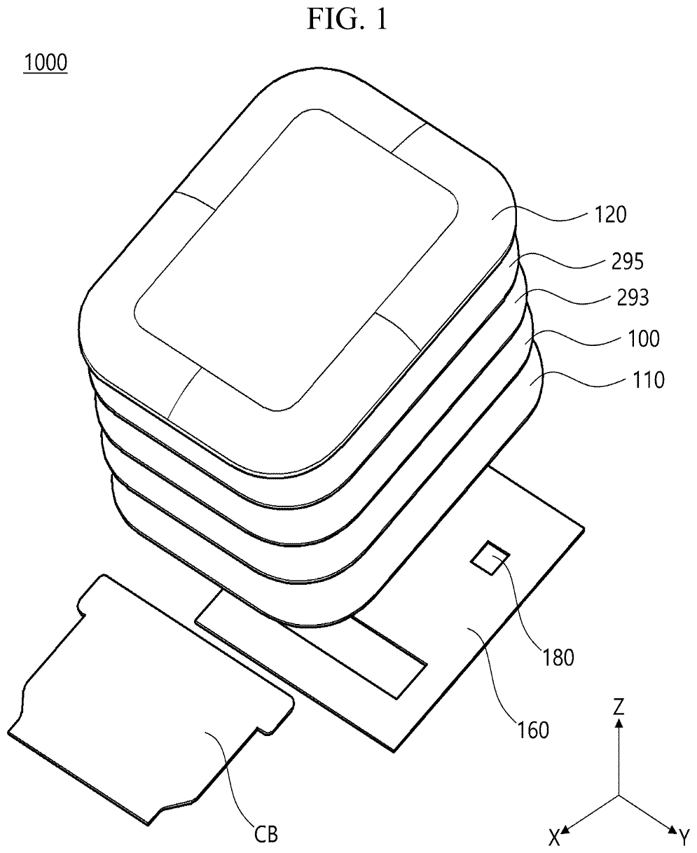

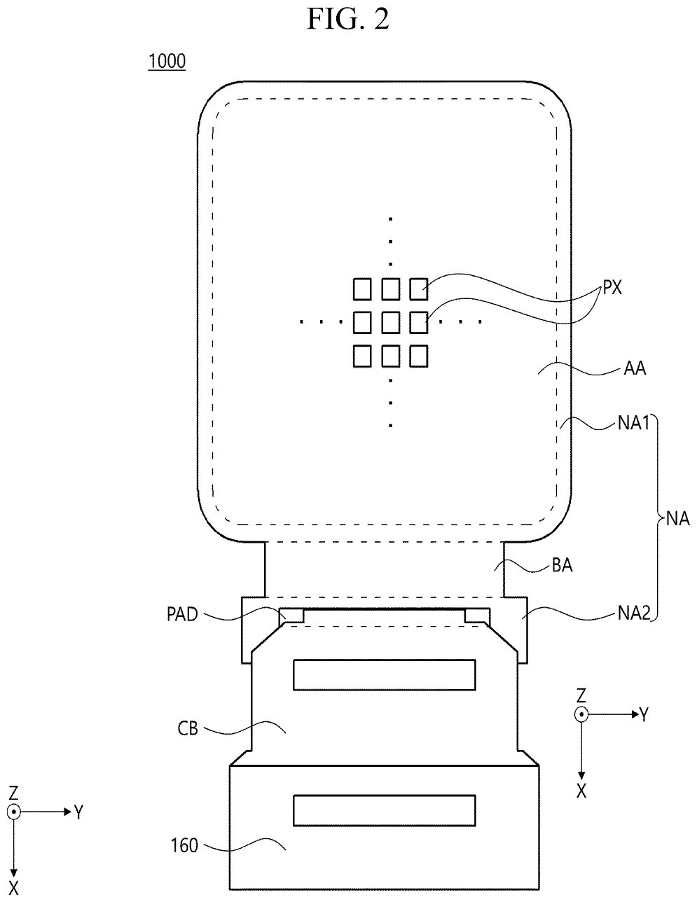

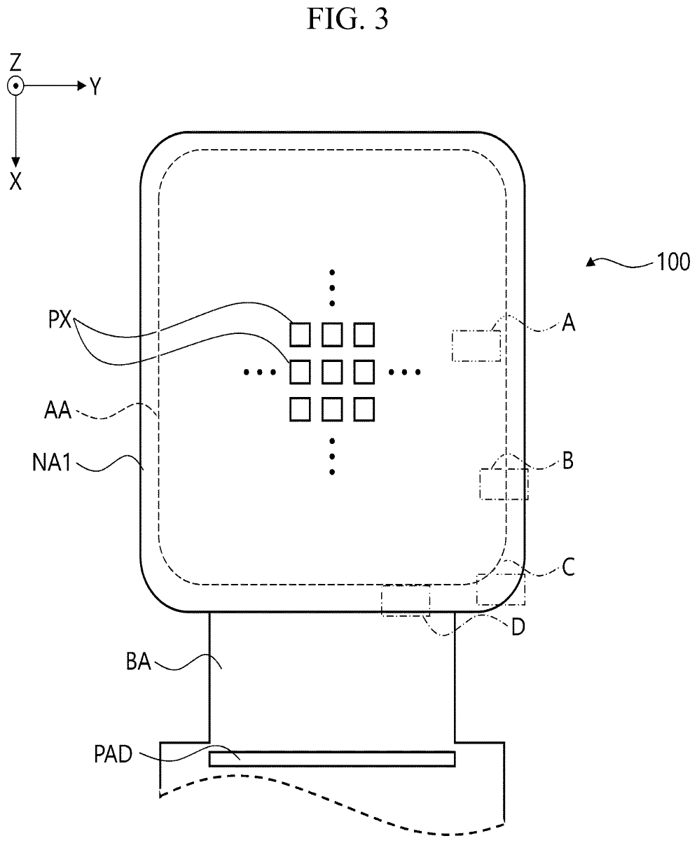

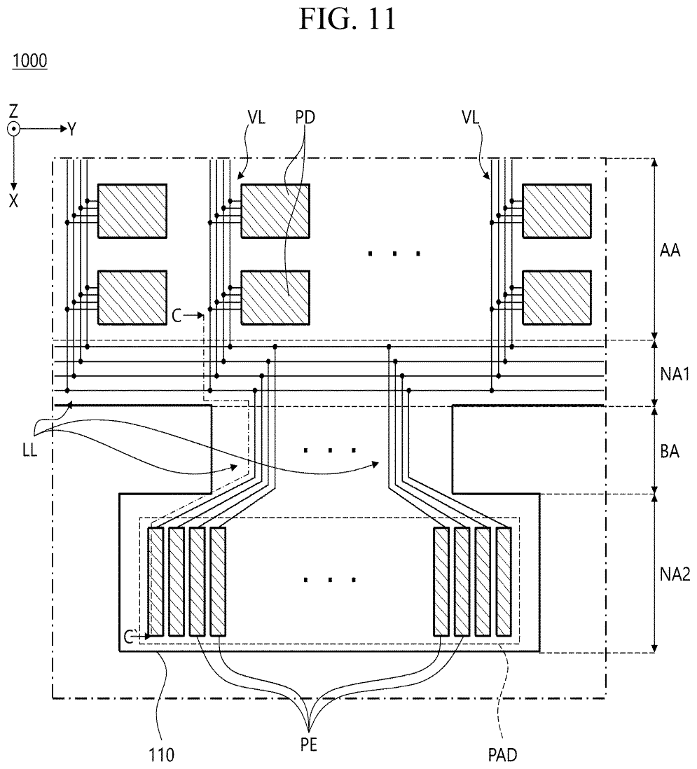

FIG. 1 is an exploded perspective view of a display apparatus according to an embodiment of the present disclosure. FIG. 2 is a plan view of the display apparatus according to an embodiment of the present disclosure. FIG. 3 is a plan view illustrating the display apparatus according to an embodiment of the present disclosure. FIG. 11 is an enlarged view illustrating the display apparatus according to an embodiment of the present disclosure.

Referring to FIGS. 1 to 3 and FIG. 11, a display apparatus 1000 according to an embodiment of the present disclosure may include a display panel 100, a polarizing layer 293, an adhesive layer 295, a cover member 120, a support substrate 110, a flexible circuit board CB, and a printed circuit board 160.

For example, the display apparatus 1000 may include a substrate 110. The substrate 110 may be a member that supports other components of the display apparatus 1000. The substrate 110 may be made of an insulating material. For example, the substrate 110 may be made of glass, resin or the like. Additionally, the substrate 110 may be made of a material having flexibility. For example, the substrate 110 may be made of a plastic material having flexibility, such as polyimide (PI). However, embodiments of the present disclosure are not limited thereto.

Information, video, and/or images to be provided to the user may be implemented on the display panel 100. For example, the display panel 100 may include a display area AA and a non-display area NA. For example, the substrate 110 may include a display area AA and a non-display area NA. The description of the display area AA and the non-display area NA may not be limited to the substrate 110, but may be applied throughout the display apparatus.

The display area AA may be an area in which images are displayed. The display area AA may include a plurality of pixels PX. Each of a plurality of pixels PX may be composed of a plurality of sub-pixels. Each of the plurality of sub-pixels may have a plurality of light-emitting elements. The plurality of light-emitting elements may be configured differently depending on the type of display apparatus 1000. For example, if the display apparatus 1000 is an inorganic light-emitting display apparatus, the light-emitting elements may be light-emitting diodes (LED), micro light-emitting diodes (micro LED), or mini light-emitting diodes (mini LED), but embodiments of the present disclosure are not limited thereto.

The non-display area NA may be an area in which no image is displayed. Various wires and circuits for driving the plurality of pixels PX in the display area AA may be arranged in the non-display area NA. For example, in the non-display area NA, various wires and driving circuits may be mounted and a pad part PAD may be arranged to which integrated circuits, printed circuits, etc. are connected, but embodiments of the present disclosure are not limited thereto.

For example, the driving circuits may be a data driving circuit and/or a gate driving circuit, but embodiments of the present disclosure are not limited thereto. Wires to which control signals for controlling the driving circuits are supplied may be arranged on the display panel 100. For example, the control signals may include various timing signals including clock signals, input data enable signals, and synchronization signals, but embodiments of the present disclosure are not limited thereto. The control signals may be received via the pad part PAD. For example, link wires LL for transmitting signals may be arranged in the non-display area NA. For example, driving components such as a flexible circuit board CB and a printed circuit board 160 may be connected to the pad part PAD.

According to one or more aspects of the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1, and may be a bendable area. The second non-display area NA2 is an area extending from the bending area BA, in which the pad part PAD may be arranged. For example, the bending area BA may be in a bent state, and the remaining area of the substrate 110 other than the bending area BA may be in a flat state. In this configuration, as the bending area BA is bent, the second non-display area NA2 may be located on the rear surface of the display area AA. However, embodiments of the present disclosure are not limited thereto.

A plurality of pixel driving circuits PD may be arranged in the display area AA. The plurality of pixel driving circuits PD may be circuits for driving light-emitting elements of a plurality of sub-pixels. Each of the plurality of pixel driving circuits PD includes a plurality of transistors, including a driving transistor, and a storage capacitor or the like, and may supply control signals, power, and driving currents to the light-emitting elements of the plurality of sub-pixels to control the light emission operation of the plurality of light-emitting elements. For example, the pixel driving circuit PD may include power wires and signal wires for controlling the light emission on/off and/or light emission duration of the light-emitting elements. For example, the plurality of pixel driving circuits PD may be drivers manufactured on a semiconductor substrate using a metal-oxide-silicon field effect transistor (MOSFET) manufacturing process, but embodiments of the present disclosure are not limited thereto. The driver may include the plurality of pixel driving circuits PD and may drive the plurality of sub-pixels.

The flexible circuit board CB and the printed circuit board 160 may be arranged on the lower portion of the display panel 100. The flexible circuit board CB and the printed circuit board 160 may be arranged on at least one side edge of the display panel 100, but embodiments of the present disclosure are not limited thereto. One side of the flexible circuit board CB may be attached to the display panel 100, and the other side may be attached to the printed circuit board 160, but embodiments of the present disclosure are not limited thereto. The flexible circuit board CB may be a flexible film, but embodiments of the present disclosure are not limited thereto.

The pad part PAD including a plurality of pad electrodes PE may be arranged in the second non-display area NA2. Driving components including one or more flexible circuit boards (or flexible films) CB and printed circuit boards 160 may be attached to or bonded to the pad part PAD. The plurality of pad electrodes PE of the pad part PAD are electrically connected to one or more flexible circuit boards (or flexible film) CB, and various signals (or power) from the printed circuit boards 160 and the flexible circuit boards (or flexible films) CB may be transmitted to the plurality of pixel driving circuits PD of the display area AA.

A flexible circuit board (or flexible film) CB may be a film with various components placed on a flexible base film. For example, a drive IC, such as a gate driver IC or a data driver IC, may be arranged on the flexible circuit board (or flexible film) CB, but embodiments of the present disclosure are not limited thereto. The drive IC may be a component that processes data and driving signals for displaying the image. The drive IC may be arranged in a manner such as a chip on glass (COG), a chip on film (COF), or a tape carrier package (TCP), depending on how it is mounted, but embodiments of the present disclosure are not limited thereto. The flexible circuit board (or flexible film) CB may be attached or bonded to the plurality of pad electrodes PE via a conductive adhesive layer, but embodiments of the present disclosure are not limited thereto.

The printed circuit board 160 may be electrically connected to one or more flexible circuit boards (or flexible films) CB and may be a component that supplies signals to the drive IC. The printed circuit board 160 may be arranged on one side of the flexible circuit board (or flexible film) CB and electrically connected to the flexible circuit board (or flexible film) CB. A variety of components for supplying different signals to the drive IC may be arranged on the printed circuit board 160. For example, various components such as a timing controller, a power supply, a memory, or a processor may be arranged on the printed circuit board 160. For example, the printed circuit board 160 may include a power management integrated circuit (PMIC), but embodiments of the present disclosure are not limited thereto.

The printed circuit board 160 may include at least one hole 180, but embodiments of the present disclosure are not limited thereto. An internal component for sensing ambient light or temperature that may be provided to a plurality of sensors may be arranged in an area corresponding to the at least one hole 180. For example, the internal component may include an ambient light sensor (ALS) or a temperature sensor, but embodiments of the present disclosure are not limited thereto. For example, the hole 180 may be a transmissive hole or the like, but embodiments of the present disclosure are not limited thereto.

The polarizing layer 293 may be arranged on the display panel 100. The polarizing layer 293 may prevent or reduce light generated from an external light source from entering the interior of the display panel 100 and affecting the light-emitting elements or the like.

The cover member 120 may be arranged on the polarizing layer 293. The cover member 120 may be a member for protecting the display panel 100. The adhesive layer 295 may be arranged between the polarizing layer 293 and the cover member 120. The cover member 120 may be attached to the display panel 100 by the adhesive layer 295. The adhesive layer 295 may include, but is not limited to, an optically cleared adhesive (OCA), an optically cleared resin (OCR), or a pressure sensitive adhesive (PSA).

The support substrate 110 may be arranged between the display panel 100 and the printed circuit board 160. The support substrate 110 may reinforce the rigidity of the display panel 100. The support substrate 110 may be a back plate, but embodiments of the present disclosure are not limited thereto.

A plurality of link wires LL may be arranged in the non-displayed area NA. The plurality of link wires LL may be wires that carries various signals from one or more flexible circuit boards (or flexible films) CB and printed circuit boards 160 to the display area AA. The plurality of link wires LL may extend from the plurality of pad electrodes PE in the second non-display area NA2 toward the bending area BA and the first non-display area NA1, and may be electrically connected to a plurality of driving wires VL in the display area AA. The plurality of pixel driving circuits PD may be driven by receiving signals from one or more flexible circuit boards (or flexible films) CB and printed circuit boards 160 via the driving wire VL in the display area AA and the link wire LL in the non-display area NA.

For example, a plurality of driving wires VL may be wires for carrying signals output from the flexible circuit board (or flexible film) CB and the printed circuit board 160, along with a plurality of link wires LL, to the plurality of pixel driving circuits PD. The plurality of driving wires VL may be arranged in the display area AA and electrically connected to each of the plurality of pixel driving circuits PD. The plurality of driving wires VL may extend from the display area AA toward the non-display area NA and be electrically connected to the plurality of link wires LL. Therefore, the signals output from the flexible circuit board (or flexible film) CB and the printed circuit board 160 may be transmitted to each of the plurality of pixel driving circuits PD via the plurality of link wires LL and the plurality of driving wires VL.

As the bending area BA is bent, portions of the plurality of link wires LL may also be bent together. Stress is concentrated in portions of the bent link wire LL, which may cause the link wires LL to crack. Accordingly, the plurality of link wires LL may be formed of a conductive material having excellent ductility to reduce cracking during bending of the bending area BA. For example, the plurality of link wires LL may be formed of a conductive material having excellent ductility such as gold (Au), silver (Ag), aluminum (Al), and the like, but embodiments of the present disclosure are not limited thereto. The plurality of link wires LL may also be formed of one of a variety of conductive materials used in the display area AA. For example, the plurality of link wires LL may be formed of molybdenum (Mo), chromium (Cr), titanium (Ti), nickel (Ni), neodymium (Nd), copper (Cu), and alloys of silver (Ag) and magnesium (Mg), or alloys thereof, but embodiments of the present disclosure are not limited thereto. The plurality of link wires LL may be formed of a multi-layer structure including various conductive materials. For example, the plurality of link wires LL may be formed of a triple-layer structure of titanium (Ti)/aluminum (Al)/titanium (Ti), but embodiments of the present disclosure are not limited thereto.

The plurality of link wires LL may be configured in various shapes to reduce stress. At least a portion of the plurality of link wires LL arranged in the bending area BA may extend in the same direction as the extension of the bending area BA, or may extend in a direction different from the extension of the bending area BA to reduce stress. For example, if the bending area BA extends in one direction from the first non-display area NA1 toward the second non-display area NA2, at least a portion of the link wires LL arranged on the bending area BA may extend in a direction that is inclined relative to the direction in which the bending area BA extends. For another example, at least a portion of the plurality of link wires LL may be configured in a pattern of various shapes. For example, at least a portion of the plurality of link wires LL arranged in the bending area BA may be a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged, but embodiments of the present disclosure are not limited thereto. Therefore, to minimize stresses concentrated in the plurality of link wires LL and resulting cracking, the shape of the plurality of link wires LL may be of various shapes including the shapes described above, but embodiments of the present disclosure are not limited thereto.

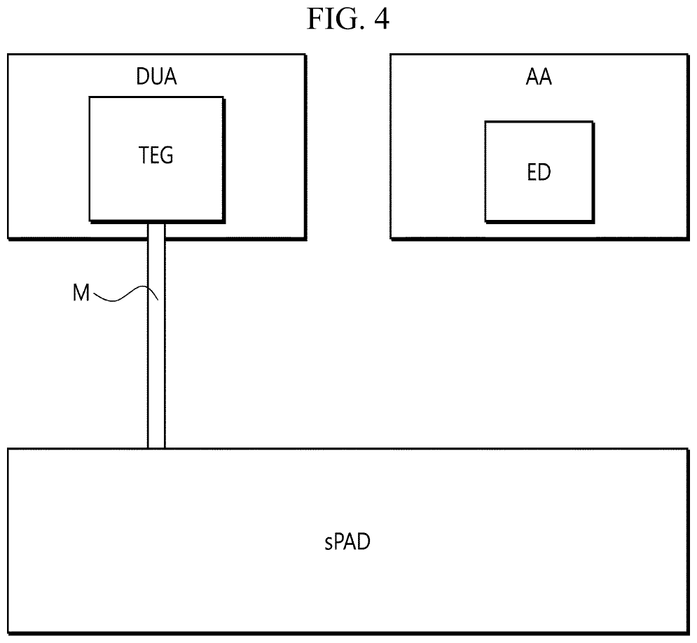

FIG. 4 is a block diagram illustrating the display apparatus according to an embodiment of the present disclosure.

Referring to FIG. 4, as described above, it may be necessary to extract data from components arranged in the display apparatus during the manufacturing process. An embodiment of the present disclosure may include a testing element group TEG structure, which is a region including a plurality of dummy light-emitting elements, a third electrode, and a wire part M. The TEG structure TEG may be a structure within a display panel designed to facilitate the extraction of the data to be measured. In the display apparatus according to one or more aspects of the present disclosure, a second electrode for supplying a cathode voltage (e.g., a low potential power voltage) to a light-emitting element ED may be arranged in the display area AA and a third electrode may be arranged in a dummy area DUA so that it is substantially the same as or similar to the light-emitting element ED arranged in the display area AA in order for the measurement of the light-emitting element ED. In addition, the wire part M may be arranged to remove noise for accurate extraction of the data value to be measured. The wire part M may include a loopback wire and/or a pad connection wire.

For example, a dummy light-emitting element arranged in the dummy area DUA, a first electrode, a first connection wire, a second connection wire, an optical layer, and the like may be utilized to measure a resistance of the light-emitting element ED arranged in the display area AA. However, this is not limited to that.

For the purpose of manufacturing the dummy area DUA, a separate electrode for supplying the cathode voltage (e.g., low potential power voltage) is not placed on the dummy light-emitting element, which serves to distinguish the display area AA from the non-display area. In order to obtain a measured value that are substantially the same or similar to the physical property value of the light-emitting element ED arranged in the display area, the display apparatus according to one or more aspects of the present disclosure may separately place the third electrode on the dummy light-emitting element and connect the wire part M to the dummy light-emitting element.

The physical property value such as the resistance of the light-emitting element ED, the resistance of the electrode, or roughness may be correlated with factors that act as CTQ (Critical to Quality) during the product's operation process. For pre-testing, monitoring, etc. of factors that may have effectively affect the operation of the product, the dummy area DUA that is expected to have a high correlation with the light-emitting element ED arranged in the display area AA may be utilized. For example, the second electrode placed in the display area AA and the third electrode placed in the dummy area DUA may both be placed on the light-emitting elements that are transferred identically. Therefore, the light-emitting element ED in the display area AA and the dummy light-emitting element in the dummy area DUA may be considered to have high correlation.

In the process of measuring the physical property value of light-emitting element using the TEG structure with high correlation, the accuracy of measuring the physical property value of the light-emitting element was not high due to other noise caused by various structures within the display panel. The noise may include line resistance from other electrodes or contact resistance between different electrodes, which is caused by the structure for measuring the resistance of the dummy light-emitting element. As such, there is a problem that the accuracy of measuring the resistance of the dummy light-emitting elements is degraded due to irregular interference from other resistances in the process of measuring the resistance of the dummy light-emitting element.

The display apparatus according to an embodiment of the present disclosure may connect the wire part M including the loopback wire and the pad connection wire having the same thickness, width, length, and cross-sectional area to the dummy light-emitting element. Therefore, the interference of noise generated in the process of utilizing the TEG structure may be improved, and the accuracy of the resistance measurement of the dummy light-emitting element may be improved. This has the advantage that the current-voltage (I-V) characteristics of the dummy LED may be measured.

Since the TEG structure TEG is used in the manufacturing process, and at least some of it may be removed after the manufacturing process. For example, at least a portion of the wire part M may be removed after the measurement.

The TEG structure TEG may be electrically connected to the pad part within the display apparatus according to an embodiment or to a separate pad sPAD external to the display apparatus during measurement. The TEG structure TEG may be intended to obtain the same/similar physical property data values as the light-emitting element ED in the display area AA, and may require a separate device to measure and/or store the property values. The separate device may include the pad part PAD within the display apparatus. The separate device may also include the separate pad sPAD that is external to the display apparatus. The separate pad sPAD may be removed from the display apparatus according to an embodiment during the manufacturing process or at the end of the manufacturing process. However, this is not limited to that.

The wire part M may electrically connect the TEG structure TEG and the separate pad sPAD. The wire part M may include various types of wires arranged within the display panel, as described later. For example, the wire part M may include a first electrode CE1, the pad electrode PE, a first connection wire 121, and a second connection wire 122, which are described later. In the final product, at least a portion of the wire part M may be removed.

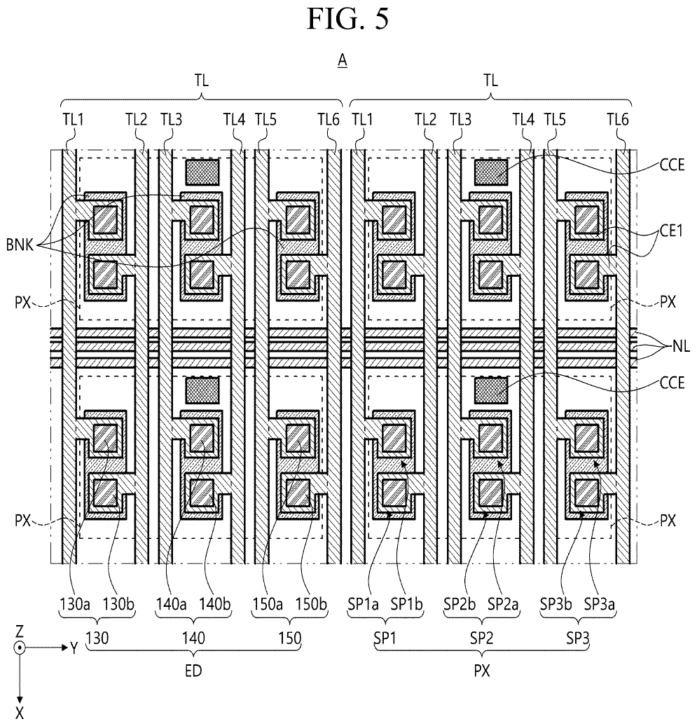

FIGS. 5 to 7 are plan views illustrating the display apparatus according to an embodiment of the present disclosure.

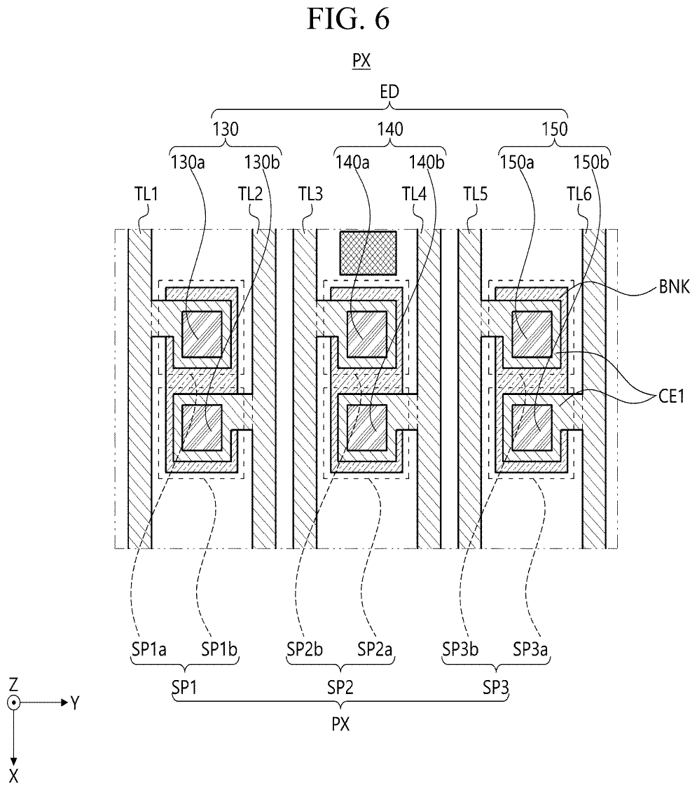

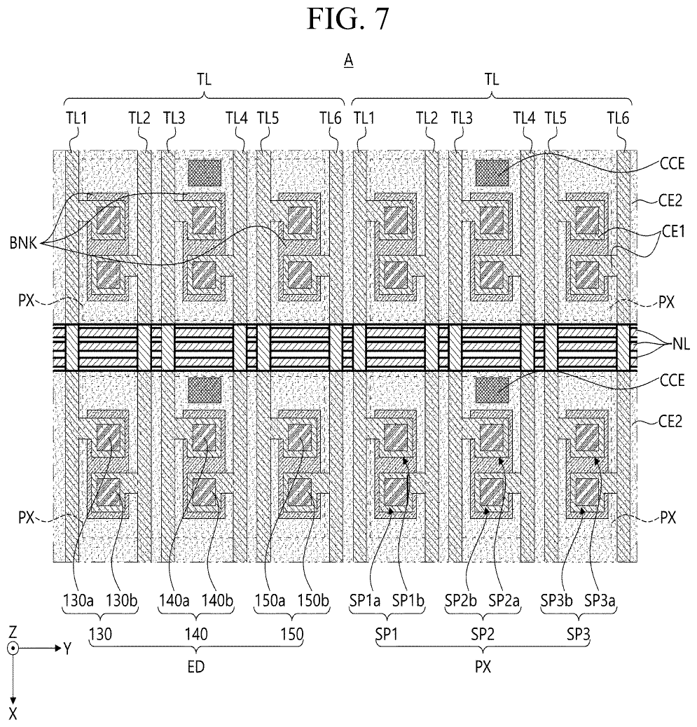

FIGS. 5 and 7 are partially enlarged views illustrating an enlarged portion A of FIG. 3. FIG. 6 is a partially enlarged view illustrating an enlarged one pixel PX.

While FIGS. 5 and 6 illustrate only a plurality of signal wires TL, a plurality of communication wires NL, a plurality of first electrodes CE1, a plurality of banks BNK, and a plurality of light-emitting elements ED, embodiments of the present disclosure are not limited thereto. FIG. 7 is an enlarged plan view in which a plurality of second electrodes CE2 are additionally arranged in FIG. 5.

Referring to FIGS. 5 to 7, a plurality of pixels PX composed of a plurality of sub-pixels may be arranged in the display area AA. Each of the plurality of sub-pixels may include a light-emitting element ED and may independently emit light. The plurality of sub-pixels may be arranged in a matrix, forming a plurality of rows and a plurality of columns, but embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another may be a green sub-pixel, and the remaining may be a blue sub-pixel. The types of the plurality of sub-pixels are examples, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. A pair of first sub-pixels SP1 may include a first-first sub-pixel SP1a and a first-second sub-pixel SP1b. A pair of second sub-pixels SP2 may include a second-first sub-pixel SP2a and a second-second sub-pixel SP2b. A pair of third sub-pixels SP3 may include a third-first sub-pixel SP3a and a third-second sub-pixel SP3b. For example, one pixel PX may include a first-first sub-pixel SP1a and a first-second sub-pixel SP1b, a second-first sub-pixel SP2a and a second-second sub-pixel SP2b, and a third-first sub-pixel SP3a and a third-second sub-pixel SP3b, but embodiments of the present disclosure are not limited thereto.

The plurality of sub-pixels that constitute one pixel PX may be arranged in a variety of ways. For example, in one pixel PX, a pair of first sub-pixels SP1 may be arranged in the same column, a pair of second sub-pixels SP2 may be arranged in the same column, and a pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX is examples, and embodiments of the present disclosure are not limited thereto.

A plurality of signal wires TL may be arranged in the area between the plurality of sub-pixels. The plurality of signal wires TL may extend in the column direction between the plurality of sub-pixels. The plurality of signal wires TL may be wires that carry anode voltages from the pixel driving circuit PD to the plurality of sub-pixels. For example, the plurality of signal wires TL may be electrically connected to the plurality of pixel driving circuits PD and the first electrodes CE1 of the plurality of sub-pixels. The anode voltages output from the pixel driving circuits PD may be transmitted to the first electrodes CE1 of the plurality of sub-pixels via the plurality of signal wires TL. For example, the first electrode CE1 may be an electrode electrically connected to the anode electrode 134 of the light-emitting element ED. Therefore, the anode voltage from the signal wire TL may be delivered to the anode electrode 134 of the light-emitting element ED via the first electrode CE1.

Consequently, instead of forming a plurality of transistors and storage capacitors for each of the plurality of sub-pixels, the structure of the display apparatus 1000 may be simplified by using a pixel driving circuit PD with an integrated plurality of pixel circuits. Further, by integrating the circuit for each of the plurality of sub-pixels into a single pixel driving circuit PD, high-efficiency, low-power operation may be achieved. The integration of the circuit for each of the plurality of sub-pixels SP into a single pixel driving circuit PD means that a pixel driving circuit PD contains a plurality of pixel circuits that can drive a plurality of light-emitting elements ED. The plurality of light-emitting elements ED may be driven by a single pixel driving circuit PD in which a plurality of pixel circuits are integrated. For example, the first-first light-emitting element 130a, the second-first light-emitting element 140a, and the third-first light-emitting element 150a may be driven by one pixel driving circuit PD in which a plurality of pixel circuits are integrated.

The plurality of signal wires TL may include a first signal wire TL1, a second signal wire TL2, a third signal wire TL3, a fourth signal wire TL4, a fifth signal wire TL5, and a sixth signal wire TL6. Each of the first signal wire TL1 and the second signal wire TL2 may be electrically connected to corresponding one of the pair of first sub-pixels SP1. Each of the third signal wire TL3 and the fourth signal wire TL4 may be electrically connected to corresponding one of the pair of second sub-pixels SP2. Each of the fifth signal wire TL5 and the sixth signal wire TL6 may be electrically connected to corresponding one of the pair of third sub-pixels SP3.

The first signal wire TL1 may be arranged on one side of the pair of first sub-pixels SP1, and the second signal wire TL2 may be arranged on the other side of the pair of first sub-pixels SP1. The first signal wire TL1 may be electrically connected to the first electrode CEL of one of the pair of first sub-pixels SP1, for example the first-first sub-pixel SP1a. The second signal wire TL2 may be electrically connected to the first electrode CE1 of the remaining one of the pair of first sub-pixels SP1, for example, the first-second sub-pixel SP1b.

The third signal wire TL3 may be arranged on one side of the pair of second sub-pixels SP2, and the fourth signal wire TL4 may be arranged on the other side of the pair of second sub-pixels SP2. For example, the third signal wire TL3 may be arranged adjacent to the second signal wire TL2. The third signal wire TL3 may be electrically connected to the first electrode CEL of one of the pair of second sub-pixels SP2, for example the second-first sub-pixel SP2a. The fourth signal wire TL4 may be electrically connected to the first electrode CE1 of the remaining one of the pair of second sub-pixels SP2, for example, the second-second sub-pixel SP2b.

The fifth signal wire TL5 may be arranged on one side of the pair of third sub-pixels SP3, and the sixth signal wire TL6 may be arranged on the other side of the pair of third sub-pixels SP3. For example, the fifth signal wire TL5 may be arranged adjacent to the fourth signal wire TL4. The sixth signal wire TL6 may be arranged adjacent to the first signal wire TL1 connected to a neighboring pixel PX. The fifth signal wire TL5 may be electrically connected to the first electrode CE1 of one of the pair of third sub-pixels SP3, for example the third-first sub-pixel SP3a. The sixth signal wire TL6 may be electrically connected to the first electrode CE1 of the remaining one of the pair of third sub-pixels SP3, for example, the third-second sub-pixel SP3b.

The plurality of signal wires TL may be made of a conductive material. For example, the plurality of signal wires TL may be formed of conductive materials such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the plurality of signal wires TL may be formed of a multi-layer structure of a conductive material. For example, the plurality of signal wires TL may be formed of a multi-layer structure of Titanium (Ti)/Aluminum (Al)/Titanium (Ti)/Indium Tin Oxide (ITO), but embodiments of the present disclosure are not limited thereto.

The plurality of communication wires NL may be arranged in the area between the plurality of pixels PX. The plurality of communication wires NL may be arranged extending in the row direction in an area between the plurality of pixels PX. The plurality of communication wires NL may be arranged in an area between the plurality of second electrodes CE2, and may not overlap the plurality of second electrodes CE2, as shown in FIG. 7. For example, the plurality of communication wires NL may be wires used for short-range communication, such as near field communication (NFC). The plurality of communication wires NL may function as antennas. For example, the plurality of communication lines NL may be a plurality of connection wires, but embodiments of the present disclosure are not limited thereto.

According to one or more aspects of the present disclosure, a bank BNK may be arranged in each of the plurality of sub-pixels. The plurality of banks BNK may be structures in which a plurality of light-emitting elements ED are seated. The plurality of banks BNK may guide the positioning of the plurality of light-emitting elements ED during a transfer process of transferring the plurality of light-emitting elements ED to the display apparatus 1000. In the process of transferring a plurality of light-emitting elements ED, the plurality of light-emitting elements ED may be transferred onto a plurality of banks BNK. The plurality of banks BNK may be a bank pattern or structure, or the like, but embodiments of the present disclosure are not limited thereto.

A bank BNK of the first sub-pixel SP1, a bank BNK of the second sub-pixel SP2, and a bank BNK of the third sub-pixel SP3 may be arranged to be spaced apart from each other. The bank BNK of the first sub-pixel SP1, the bank BNK of the second sub-pixel SP2, and the bank BNK of the third sub-pixel SP3 may be configured to be separate. In this way, the banks BNK of the first sub-pixels SP1, the second sub-pixels SP2, and the third sub-pixels SP3, to which different types of light-emitting elements ED are transferred, may be easily identified.

The bank BNK of the first-first sub-pixel SP1a and the bank BNK of the first-second sub-pixel SP1b may be connected to each other, or may be spaced apart from each other or formed separately from each other. For example, the bank BNK of the first-first sub-pixel SP1a and the bank BNK of the first-second sub-pixel SP1b, in which the same type of light-emitting elements ED are arranged, may be connected to each other, spaced apart, or separated from each other in consideration of the design such as the transfer process requirements, etc. The bank BNK of the second-first sub-pixel SP2a and the bank BNK of the second-second sub-pixel SP2b may also be connected to each other, or may also be spaced apart or separated from each other. The bank BNK of the third-first sub-pixel SP3a and the bank BNK of the third-second sub-pixel SP3b may be connected to each other, or may be spaced apart from each other or formed separately from each other. Therefore, the banks BNK of the pair of first sub-pixels SP1, the banks BNK of the pair of second sub-pixels SP2, and the bank BNKs of the pair of third sub-pixels SP3 may be formed in various ways, and embodiments of the present disclosure are not limited thereto.

For example, the plurality of banks BNK may be made of an organic insulating material. The plurality of banks BNK may be formed of a single or multi-layer of an organic insulating material. For example, the plurality of banks BNK may be made of a photo resist, polyimide (PI), or acryl-based material, but embodiments of the present disclosure are not limited thereto.

The first electrode CE1 may be arranged on each of the plurality of sub-pixels. The first electrode CE1 may be arranged on the bank BNK. The first electrode CE1 may be electrically connected to one of the plurality of signal wires TL. At least a portion of the first electrode CE1 may extend outwardly of the bank BNK and may be electrically connected to the signal wire TL closest to the such electrode CE1. For example, a portion of the first electrode CE1 of the first-first sub-pixel SP1a may extend to one side area of the first-first sub-pixel SP1a and be electrically connected to the first signal wire TL1, and a portion of the first electrode CE1 of the first-second sub-pixel SP1b may extend to the other side area of the first-second sub-pixel SP1b and be electrically connected to the second signal wire TL2. A portion of the first electrode CE1 of the second-first sub-pixel SP2a may extend to one side area of the second-first sub-pixel SP2a and be electrically connected to the third signal wire TL3, and a portion of the first electrode CE1 of the second-second sub-pixel SP2b may extend to the other side area of the second-second sub-pixel SP2b and be electrically connected to the fourth signal wire TL4. A portion of the first electrode CE1 of the third-first sub-pixel SP3a may extend into one side area of the third-first sub-pixel SP3a and be electrically connected to the fifth signal wire TL5, and a portion of the first electrode CE1 of the third-second sub-pixel SP3b may extend into the other side area of the third-second sub-pixel SP3b and be electrically connected to the sixth signal wire TL6.

The first electrode CE1 is electrically connected to an anode electrode 134 of the light-emitting element ED, and may transmit the anode voltage from the pixel driving circuit PD to the light-emitting element ED via the signal wire TL. Different voltages may be applied to the first electrode CE1 of each of the plurality of sub-pixels depending on the image being displayed. For example, different voltages may be applied to the first electrode CE1 of each of the plurality of sub-pixels. Thus, the first electrode CE1 may be a pixel electrode, and embodiments of the present disclosure are not limited thereto.

The first electrode CE1 may be formed of a conductive material. For example, the first electrode CE1 may be integrally configured with the plurality of signal wires TL. For example, the first electrode CE1 may be formed of the same conductive material as the plurality of signal wires TL, but embodiments of the present disclosure are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the first electrode CE1 may be formed of a multi-layer structure of a conductive material. For example, the plurality of first electrodes CE1 may be made of a multi-layer structure of Titanium (Ti)/Aluminum (Al)/Titanium (Ti)/Indium Tin Oxide (ITO), but embodiments of the present disclosure are not limited thereto.

A light-emitting element ED may be arranged in each of the plurality of sub-pixels. A plurality of light-emitting elements ED may be either light-emitting diodes (LED) or micro light-emitting diodes (micro LED), but embodiments of the present disclosure are not limited thereto. The plurality of light-emitting elements ED may be arranged on the bank BNK and the first electrode CE1. The plurality of light-emitting elements ED are arranged on the first electrode CE1 and may be electrically connected to the first electrode CE1. Therefore, the light-emitting element ED may emit light by receiving an anode voltage from the pixel driving circuit PD via the signal wire TL and the first electrode CE1.

The plurality of light-emitting elements ED may include a first light-emitting element 130, a second light-emitting element 140, and a third light-emitting element 150. The first light-emitting element 130 may be arranged in the first sub-pixel SP1. The second light-emitting element 140 may be arranged in the second sub-pixel SP2. The third light-emitting element 150 may be arranged in the third sub-pixel SP3. For example, one of the first light-emitting element 130, the second light-emitting element 140, and the third light-emitting element 150 may be a red light-emitting element, another may be a green light-emitting element, and the remaining may be a blue light-emitting element, but embodiments of the present disclosure are not limited thereto. Accordingly, various colors of light, including white, may be implemented by combining red light, green light, and blue light emitted by the plurality of light-emitting elements ED. The types of the plurality of light-emitting elements ED are examples, and embodiments of the present disclosure are not limited thereto.

The first light-emitting element 130 may include the first-first light-emitting element 130a arranged in the first-first sub-pixel SP1a and the first-second light-emitting element 130b arranged in the first-second sub-pixel SP1b. The second light-emitting element 140 may include the second-first light-emitting element 140a arranged in the second-first sub-pixel SP2a and the second-second light-emitting element 140b arranged in the second-second sub-pixel SP2b. The third light-emitting element 150 may include a third-first light-emitting element 150a arranged in the third-first sub-pixel SP3a and the third-second light-emitting element 150b arranged in the third-second sub-pixel SP3b.

The second electrode CE2 may be arranged on each of the plurality of sub-pixels. The second electrode CE2 may be arranged on the light-emitting element ED. The second electrode CE2 may be electrically connected to the pixel driving circuit PD via a plurality of contact electrodes CCE.

For example, the second electrode CE2 may be electrically connected to a cathode electrode 135 of the light-emitting element ED to transmit the cathode voltage from the pixel driving circuit PD to the light-emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light-emitting element ED. Thus, the second electrode CE2 may be a common electrode, but embodiments of the present disclosure are not limited thereto.

At least some of the plurality of sub-pixels may share the second electrode CE2. The second electrodes CE2 of at least some of the plurality of sub-pixels may be electrically connected to each other. Since the same voltage is applied to the second electrodes CE2, the second electrodes CE2 of at least some of the sub-pixels may be shared and used. For example, the second electrodes CE2 of at least some of the plurality of pixels PXs arranged in the same row may be connected to each other. For example, one second electrode CE2 may be arranged on a plurality of pixels PX. One second electrode CE2 may be arranged for every n sub-pixels.

For example, some of the second electrodes CE2 of the plurality of sub-pixels may be spaced apart or separated from each other. For example, the second electrode CE2 connected to an (n)th row of pixels PX and the second electrode CE2 connected to an (n+1)th row of pixels PX may be spaced apart or separated from each other. For example, the plurality of second electrodes CE2 may be spaced apart from each other with a plurality of communication wires NL extending in the row direction interposed therebetween. Thus, the number of the plurality of sub-pixels may be greater than the number of the plurality of second electrodes CE2. For other examples, the second electrodes CE2 of the plurality of sub-pixels may all be connected to each other so that only one second electrode CE2 is arranged on the substrate 110, and embodiments of the present disclosure are not limited thereto.

The plurality of second electrodes CE2 may be formed of a transparent conductive material, but embodiments of the present disclosure are not limited thereto. The plurality of second electrodes CE2 may be made of a transparent conductive material, such that light emitted from the light-emitting element ED is directed onto the upper portion of the second electrode CE2. For example, the second electrode CE2 may made of a transparent conductive material such as Indium Tin Oxide (ITO), Indium Zinc Oxide (IZO), Indium Gallium Zinc Oxide (IGZO), or the like, but embodiments of the present disclosure are not limited thereto.

A plurality of contact electrodes CCE may be arranged on the substrate 110. For example, a plurality of contact electrodes CCE may be arranged to be spaced apart from the plurality of banks BNK and the plurality of signal wire TL. Each of the plurality of second electrodes CE2 may overlap at least one contact electrode CCE. For example, one second electrode CE2 may overlap a plurality of contact electrodes CCE.

For example, a plurality of contact electrodes CCE may be electrically connected to a plurality of second electrodes CE2. The plurality of contact electrodes CCE are arranged between the substrate 110 and the plurality of second electrodes CE2 to supply the cathode voltage from the pixel driving circuit PD to the second electrodes CE2.

For example, when micro-LEDs are used as the light-emitting elements ED, the display apparatus 1000 may be manufactured by forming a plurality of micro-LEDs on a wafer and transferring the micro-LEDs to the substrate 110 of the display apparatus 1000. Various defects may occur in the process of transferring a plurality of light-emitting elements ED having a fine size from a wafer to the substrate 110. For example, some sub-pixels may have untransferred defects in which the light-emitting elements ED are not transferred, while other sub-pixels may have transferred defects in which the light-emitting elements ED are out of position due to misalignment. In addition, the transfer process has been completed normally, but the transferred light-emitting element ED itself may be defective. Therefore, a plurality of light-emitting elements ED of the same type may be transferred to one sub-pixel, taking into account the defects during the transfer process of a plurality of light-emitting elements ED. A test for illuminating the plurality of light-emitting elements ED is conducted, and only one light-emitting element ED that is finally judged to be normal can be used.

For example, the first-first light-emitting element 130a and the first-second light-emitting element 130b may be transferred together to one pixel PX and inspected for defects. When both the first-first light-emitting element 130a and the first-second light-emitting element 130b are determined to be normal, only the first-first light-emitting element 130a may be used and the first-second light-emitting element 130b may not be used. For another example, when only the first-second light-emitting element 130b among the first-first light-emitting element 130a and the first-second light-emitting element 130b is determined to be normal, the first-first light-emitting element 130a may not be used and only the first-second light-emitting element 130b may be used. Therefore, even if a plurality of light-emitting elements ED of the same type are transferred to one pixel PX, only one light-emitting element ED may be used at the end.

Thus, one of the pair of light-emitting elements ED may be the main or primary ED and the other may be a redundancy ED. A redundancy light-emitting element ED may be a spare light-emitting element ED in preparation for a defect in the main light-emitting element ED. The redundancy light-emitting element ED may be used as a replacement in case the main light-emitting element ED is defective. Therefore, the main and redundancy light-emitting elements ED may be transferred together on one pixel PX to minimize the deterioration of the display quality due to the defects of the main and redundancy light-emitting elements ED.

For example, the first-first light-emitting element 130a, second-first light-emitting element 140a, and third-first light-emitting element 150a transferred to one pixel PX may be used as the main light-emitting elements ED, and the first-second light-emitting element 130b, second-second light-emitting element 140b, and third-second light-emitting element 150b may be used as the redundancy light-emitting elements ED.

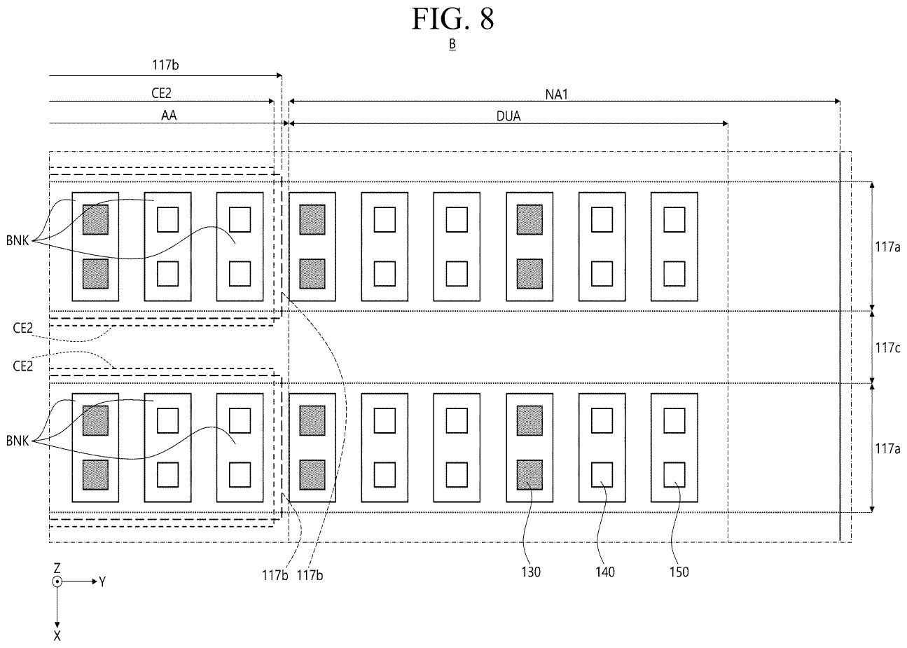

FIGS. 8 to 10 are plan views illustrating the display apparatus according to an embodiment of the present disclosure. The same reference numbers are assigned to substantially the same configuration between embodiments, and repeated descriptions are omitted.

FIG. 8 is a plan view illustrating the display area and the non-display area according to an embodiment of the present disclosure. FIG. 8 is partially enlarged view illustrating an enlarged portion B of FIG. 3.

Referring to FIG. 8, the display area AA may include the plurality of light-emitting elements 130, 140, and 150, the second electrode CE2, a first optical layer 117a, a second optical layer 117b, and a third optical layer 117c. The first non-display area NA1 may include the plurality of light-emitting elements 130, 140, and 150, the first optical layer 117a, the second optical layer 117b, and the third optical layer 117c. The third electrode is not shown.

The plurality of light-emitting elements 130, 140, and 150 may be arranged in the display area AA. In addition, the optical layers 117a, 117b, and 117c around the plurality of light-emitting elements 130, 140, and 150 may be arranged in the display area AA. For example, the optical layers 117a, 117b, and 117c surrounding a plurality of light-emitting elements 130, 140, and 150 may be arranged in the display area AA. The optical layer in the plurality of light-emitting elements 130, 140, and 150 or around the plurality of light-emitting elements 130, 140, and 150 may include the third optical layer 117c. For example, the optical layer surrounding the plurality of light-emitting elements 130, 140, and 150 may include the third optical layer 117c. The plurality of light-emitting elements 130, 140, and 150 may be inorganic light-emitting elements or micro-LEDs.

The pixel PX may include the plurality of light-emitting elements 130, 140, and 150. The third optical layer 117c may be arranged between the plurality of pixels PX. The plurality of pixels PX arranged in the display area AA may overlap the second electrode CE2 in the plane direction of the display panel. In one embodiment, the plurality of pixels PX arranged in the second direction (e.g., Y-axis direction) may overlap the second electrode CE2 in the plane direction of the display panel. The second electrode CE2 may be arranged along a direction in which the plurality of pixels PX are arranged.

The display panel according to one embodiment may include the second electrode CE2 arranged to extend in the second direction. The second electrode CE2 may be arranged in multiple in the first directions (e.g., the X-axis direction).

The plurality of light-emitting elements 130, 140, and 150 arranged in the display area AA may emit light by a high potential power voltage applied to the first electrode as the plurality of second electrodes CE2 are arranged. The second electrode CE2 may be formed to entirely cover the plurality of pixels so as to be common to the plurality of pixels. The second electrode CE2 may be formed to be common to only the plurality of light-emitting elements 130, 140, and 150 arranged on each pixel, but is not limited thereto.

The plurality of light-emitting elements 130, 140, and 150 arranged in the display area AA and the first non-display area NA1 may include the first light-emitting element 130, the second light-emitting element 140, and the third light-emitting element 150. The first light-emitting element 130, the second light-emitting element 140, and the third light-emitting element 150 may implement a first color, a second color, and a third color, respectively. The first to third colors may be any one of red, green, and blue that do not repeat with each other, but embodiments of the present disclosure are not limited thereto. For example, the first color may be red, the second color may be green, and the third color may be blue, but are not limited thereto.

The first light-emitting element 130 may have a first size, the second light-emitting element 140 may have a second size, and the third light-emitting element 150 may have a third size. The first size may be different from the second size and/or the third size. The first size may be larger than the second size and/or the third size. By designing the first size of the first light-emitting element 130 implementing the first color differently from the second size of the second light-emitting element 140 and/or the third size of the third light-emitting element 150, the light efficiency of the display apparatus may be improved. However, this is not limited to that.

The first non-display area NA1 may include the dummy area DUA. The dummy area DUA may include a dummy pixel including a plurality of dummy light-emitting elements. The second electrode CE2 may not be arranged in the first non-display area NA1 in which the plurality of dummy light-emitting elements are arranged. Therefore, even if a high potential power voltage is applied to the first electrode arranged on the dummy light-emitting element, the dummy light-emitting element may not emit light. However, if a third electrode is arranged on the dummy light-emitting element according to an embodiment of the present disclosure, the dummy light-emitting element may emit light.

One pixel may include the first light-emitting element 130, the second light-emitting element 140, and the third light-emitting element 150. The third optical layer 117c may be arranged between the plurality of pixels arranged in the first direction (e.g., the X-axis). For example, the third optical layer 117c may be arranged to extend in the second direction (e.g., the Y-axis direction) that intersects the first direction.

The first optical layer 117a and the second optical layer 117b may be arranged to overlap each other in an area in which the pixels or the dummy pixels are arranged and in the plan direction of the display panel (e.g., the z-axis direction). The third optical layer 117c may be arranged (e.g., in the x-axis direction) between the plurality of first optical layers 117a or between the plurality of second optical layers 117b.

In one embodiment, the first optical layer 117a may extend to one end of the display panel. The second optical layer 117b may be arranged in the display area AA. The second optical layer 117b may be arranged on the first optical layer 117a. Therefore, the thickness of the optical layer of the display panel may decrease toward the second direction (e.g., the Y-axis direction). The ends (or one sides) of the second electrode CE2 and the second optical layer 117b in the first direction may be formed to meet at substantially the same point as each other. The display area AA may include the second electrode CE2 and the second optical layer 117b.

A passivation layer may be arranged across the display area AA and the first non-display area NA1. Since the display apparatus according to an embodiment of the present disclosure includes the passivation layer, moisture penetration from the outside of the display apparatus may be prevented, which may improve the life of the display apparatus. This may provide a display apparatus with reduced power consumption and low-power operation.

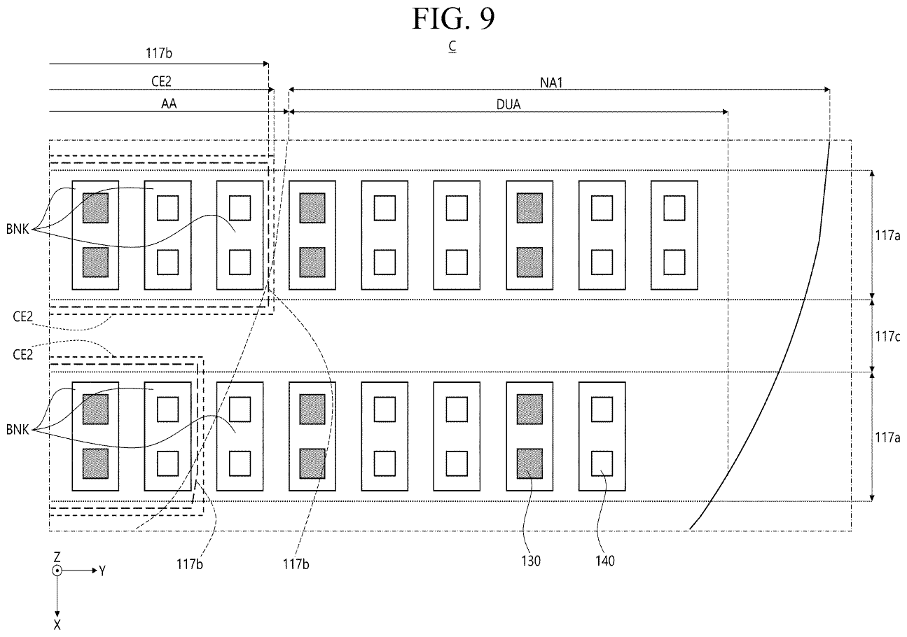

FIG. 9 is a plan view illustrating the display area and the non-display area according to an embodiment of the present disclosure. FIG. 9 is a partially enlarged view illustrating an enlarged portion C of FIG. 3.

Referring to FIG. 9, the display apparatus may include the display area AA and the first non-display area NA1. The ends of the second electrode CE2 and the second optical layer 117b in the first direction may be formed to meet at substantially the same point as each other. The display area AA may include the second electrode CE2 and the second optical layer 117b. The third electrode is not shown.

The display apparatus may include rounded corners, but embodiments of the present disclosure are not limited thereto. The second electrode CE2, the second optical layer 117b, and the like may be formed to correspond to the rounded corners. The plurality of light-emitting elements 130 and 140 may also be formed to correspond to the corners.

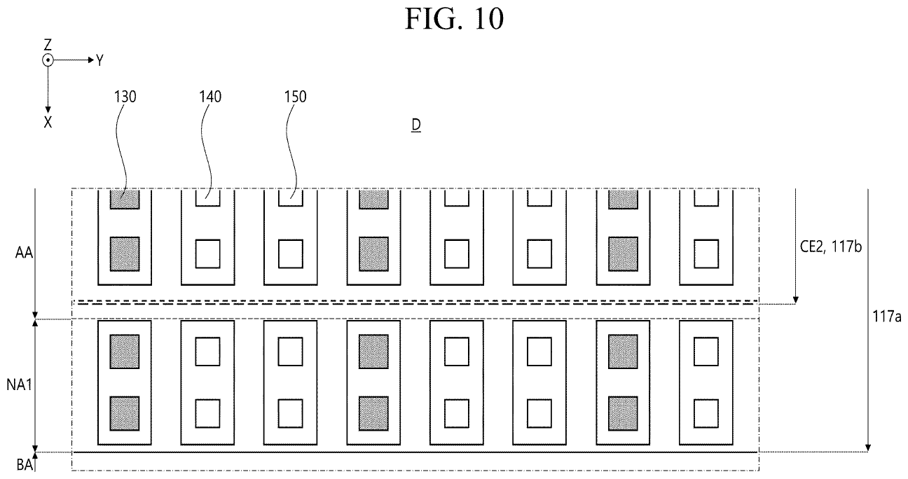

FIG. 10 is a plan view illustrating the display area and the non-display area according to an embodiment of the present disclosure. FIG. 10 is a partially enlarged view illustrating an enlarged portion D of FIG. 3.

Referring to FIG. 10, the display apparatus may include the display area AA and the first non-display area NA1. The ends of the second electrode CE2 and the second optical layer 117b in the first direction may be formed to meet at substantially the same point as each other. The display area AA may include the second electrode CE2 and the second optical layer 117b.

The display apparatus may include the first non-display area NA1 arranged between the bending area BA and the display area AA.

The passivation layer may be arranged across the display area AA and the first non-display area NA1. The display apparatus according to an embodiment of the present disclosure may include the passivation layer that prevents moisture from entering the display apparatus from outside the display apparatus, thereby improving the life of the display apparatus. This may result in lower power consumption and low-power operation in the long term.

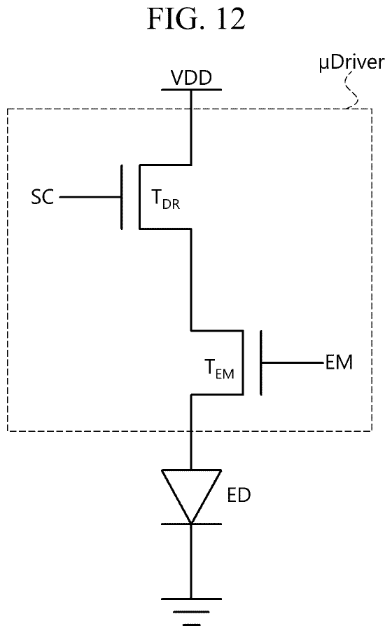

FIG. 12 is a diagram illustrating a circuit structure according to an embodiment of the present disclosure.

Although FIG. 12 illustrates one light-emitting element ED connected to a micro-driver μDriver, it is not limited thereto. For example, eight light-emitting elements ED may be connected to one micro-driver μDriver. For another example, 16 light-emitting elements ED may be connected to one micro-driver, or 32 light-emitting elements ED or 64 light-emitting element ED may be connected to one micro-driver. The light-emitting element ED may be a micro light-emitting element (μLED).

One micro-driver μDriver may include a driving transistor T_{DR} and a light emitting transistor T_{EM}, but embodiments of the present disclosure are not limited thereto.

For example, the driving transistor T_{DR} may have a first electrode to which a high potential power voltage VDD is applied, a second electrode connected to a first electrode of the light emitting transistor TEM, and a gate electrode to which a scan signal SC is applied. The scan signal SC applied to the gate electrode of the driving transistor T_{DR} may be a direct current power source, which may be applied as a fixed reference voltage (Vref) every frame, but embodiments of the present disclosure are not limited thereto.

The light-emitting transistor T_{EM} may have a first electrode connected to the second electrode of the driving transistor T_{DR}, a second electrode connected to the light-emitting element ED, and a gate electrode to which the emission signal EM is applied. The emission signal EM applied to the gate electrode of the light emitting transistor T_{EM} may be a pulse width modulation signal that varies every frame, but embodiments of the present disclosure are not limited thereto.

The first electrode of the light-emitting element ED may be connected to the second electrode of the light emitting transistor T_{EM}, and the second electrode of the light-emitting element ED may be connected to ground. For example, the first electrode of the light-emitting element ED may be an anode electrode and the second electrode of the light-emitting element ED may be a cathode electrode, but embodiments of the present disclosure are not limited thereto.

Each of the driving transistor T_{DR} and the light emitting transistor T_{EM} may be n-type transistors or p-type transistors.

In the micro-driver μDriver, the driving transistor T_{DR} may be turned on by the scan signal SC applied from the timing controller T-CON, and the light emitting transistor T_{EM} may be turned on by the light emitting signal EM. Accordingly, a driving current is applied to the light-emitting element ED through the driving transistor T_{DR} and the light emitting transistor T_{EM} by the high-potential power voltage VDD applied to the first electrode of the driving transistor T_{DR}, thereby causing the light-emitting element ED to emit light.

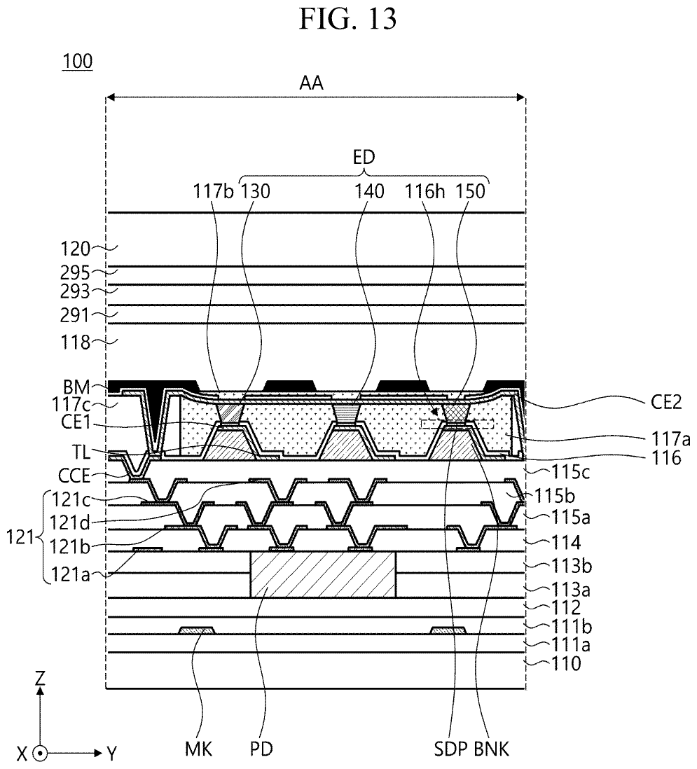

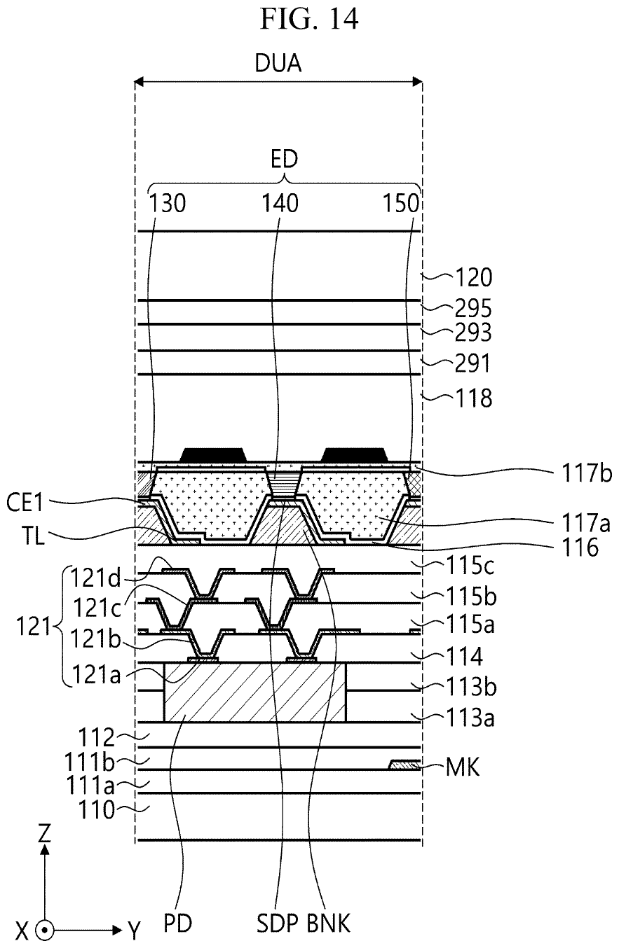

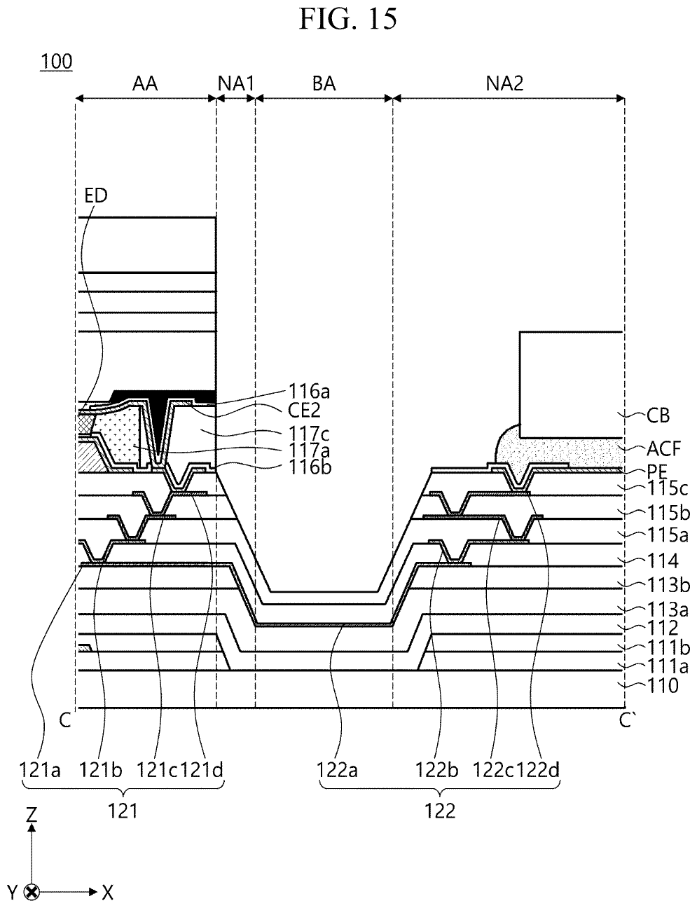

FIGS. 13 and 15 are cross-sectional views illustrating the display apparatus according to an embodiment of the present disclosure. FIG. 14 is a cross-sectional view illustrating the display apparatus according to an embodiment of the present disclosure.

FIGS. 13 and 15 are cross-sectional views of the display area AA, the first non-display area NA1, the bending area BA, and the second non-display area NA2. FIG. 14 is a cross-sectional view of the dummy area DUA within the first non-displayed area.

Referring to FIGS. 13 to 15, a first buffer layer 111a and a second buffer layer 111b may be arranged on the remaining areas of the substrate 110 except for the bending area BA.

The first buffer layer 111a and the second buffer layer 111b may be arranged in the display area AA, the first non-display area NA1, and the second non-display area NA2. The first buffer layer 111a and the second buffer layer 111b may reduce the penetration of moisture or impurities through the substrate 110. The first buffer layer 111a and the second buffer layer 111b may be made of an inorganic insulating material. For example, the first buffer layer 111a and the second buffer layer 111b may be formed of a single layer or a multi-layer of silicon oxide (SiOx) or silicon nitride (SiNx), but embodiments of the present disclosure are not limited thereto.

For example, portions of the first buffer layer 111a and the second buffer layer 111b on the bending area BA may be removed. The top surface of the substrate 110 located in the bending area BA may be exposed from the first buffer layer 111a and the second buffer layer 111b. By removing the first buffer layer 111a and the second buffer layer 111b, which are made of an inorganic insulating material, from the bending area BA, cracking of the first buffer layer 111a and the second buffer layer 111b that may occur during bending may be minimized.

A plurality of alignment keys MK may be arranged between the first buffer layer 111a and the second buffer layer 111b. The plurality of alignment keys MK may be configured to identify position of the pixel driving circuit PD during the manufacturing process of the display apparatus 1000. For example, the plurality of alignment keys MK may be configured to align the position of the pixel driving circuit PD that is transferred onto the adhesive layer 112. For another example, the plurality of alignment keys MK may be omitted.

An adhesive layer 112 may be arranged on the second buffer layer 111b. The adhesive layer 112 may be arranged in the display area AA and the first non-display area NA1, and the bending area BA and the second non-display area NA2. For another example, at least a portion of the adhesive layer 112 may be removed from the non-display area NA that includes the bending area BA. For example, the adhesive layer 112 may be made of any of a polymer, epoxy resin, UV curable resin, polyimide-based, acrylate-based, urethane-based, and polydimethylsiloxane (PDMS), but embodiments of the present disclosure are not limited thereto.

In the display area AA, the pixel driving circuit PD may be arranged on the adhesive layer 112. If the pixel driving circuit PD is implemented as a driver, the driver may be mounted on the adhesive layer 112 by a transfer process, but embodiments of the present disclosure are not limited thereto.

A first protective layer 113a and a second protective layer 113b may be arranged on the adhesive layer 112 and the pixel driving circuit PD. The first protective layer 113a and the second protective layer 113b may be arranged to surround the side surfaces of the pixel driving circuit PD, but embodiments of the present disclosure are not limited thereto. For example, the second protective layer 113b may be arranged to cover at least a portion of the top surface of the pixel driving circuit PD. For example, at least one of the first protective layer 113a and the second protective layer 113b arranged on the bending area BA may be omitted. For example, the first protective layer 113a may be arranged entirely in the display area AA and the non-display area NA, and the second protective layer 113b may be arranged partially in the display area AA, the first non-display area NA1, and the second non-display area NA2. For example, a portion of the second protective layer 113b in the bending area BA may be removed. However, embodiments of the present disclosure are not limited thereto.

The first protective layer 113a and the second protective layer 113b may be formed of an organic insulating material, but embodiments of the present disclosure are not limited thereto. For example, the first protective layer 113a and the second protective layer 113b may be formed of a photo resist, polyimide (PI), or photo acryl-based material, but embodiments of the present disclosure are not limited thereto. For example, the first protective layer 113a and the second protective layer 113b may be an overcoating layer or an insulating layer, but embodiments of this specification are not limited thereto.

According to one or more aspects of the present disclosure, the plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected via a plurality of first connection wires 121 to a plurality of signal wires TL and a plurality of contact electrodes CCE, and the like. For example, the plurality of first connection wires 121 may include a first-first connection wire 121a, a first-second connection wire 121b, a first-third connection wire 121c, and a first-fourth connection wire 121d, but embodiments of the present disclosure are not limited thereto. The first connection wire 121 and the second connection wire 122 may be formed or deposited in the same step of the manufacturing process, except for the differences in their arranged positions (the first connection wire 121 is arranged in the display area, and the second connection wire 122 is arranged in the bending area and the second non-display area).

For example, a plurality of first-first connection wire 121a may be arranged on the second protective layer 113b. The plurality of first-first connection wires 121a may be electrically connected to the pixel driving circuit PD. The plurality of first-first connection wires 121a may transmit the voltage output from the pixel driving circuit PD to the first electrode CE1 or the second electrode CE2.

For example, a third protective layer 114 may be arranged on the second protective layer 113b. The third protective layer 114 may be entirely arranged in the display area AA and the non-display area NA. In the bending area BA, the third protective layer 114 may cover the side surface of the second protective layer 113b and the top surface of the first protective layer 113a. The third protective layer 114 may be formed of an organic insulating material. For example, the third protective layer 114 may be formed of a photo resist, polyimide (PI), or photo acryl-based material, but embodiments of the present disclosure are not limited thereto. For example, the first protective layer 113a, the second protective layer 113b, and the third protective layer 114 may be formed of the same material, but embodiments of the present disclosure are not limited thereto. For example, the first protective layer 113a, the second protective layer 113b, and the third protective layer 114 may be insulating layers, but embodiments of the present disclosure are not limited thereto.

A plurality of first-second connection wires 121b may be arranged on the third protective layer 114. The plurality of first-second connection wires 121b may be connected to or directly connected to the pixel driving circuit PD. For example, some of the first-second connection wires 121b may be directly connected to the pixel driving circuit PD via contact holes in the third protective layer 114. The other of the first-second connection wires 121b may be electrically connected to the first-first connection wire 121a via the contact holes in the third protective layer 114. However, embodiments of the present disclosure are not limited thereto. The voltage output from the pixel driving circuit PD may be transmitted to the first electrode CE1 or the second electrode CE2 via the plurality of first-second connection wires 121b and other connection wires.

A first insulating layer 115a may be formed on the plurality of first-second connection wires 121b. The first insulating layer 115a may be entirely arranged in the display area AA and the non-display area NA, but embodiments of the present disclosure are not limited thereto. The first insulating layer 115a may be formed of an organic insulating material, but embodiments of the present disclosure are not limited thereto. For example, the first insulating layer 115a may be formed of a photo resist, polyimide (PI), or photo acryl-based material, but embodiments of the present disclosure are not limited thereto.

A plurality of first-third connection wires 121c may be arranged on the first insulating layer 115a. The first-third connection wires 121c may be electrically connected to the plurality of first-second connection wire 121b. For example, the first-third connection wires 121c may be electrically connected to the first-second connection wires 121b via contact holes of the first insulating layer 115a.

A second insulating layer 115b may be arranged on the plurality of first-third connection wires 121c. The second insulating layer 115b may be arranged in the remaining area except for the bending area BA, but embodiments of the present disclosure are not limited thereto. The second insulating layer 115b may be arranged in the display area AA, the first non-display area NA1, and the second non-display area NA2, but embodiments of the present disclosure are not limited thereto. For example, a portion of the second insulating layer 115b arranged in the bending area BA may be removed. The second insulating layer 115b may be formed of an organic insulating material, but embodiments of the present disclosure are not limited thereto. For example, the second insulating layer 115b may be formed of a photo resist, polyimide (PI), or photo acryl-based material, but embodiments of the present disclosure are not limited thereto.

A plurality of first-fourth connection wires 121d may be arranged on the second insulating layer 115b. The plurality of first-fourth connection wires 121d may be electrically connected to the plurality of first-third connection wires 121c. For example, the first-fourth connection wires 121d may be electrically connected to the first-third connection wires 121c via contact holes of the second insulating layer 115b.

According to one or more aspects of the present disclosure, the plurality of second connection wires 122 may be arranged on the second protective layer 113b in the non-display area NA. The plurality of second connection wires 122 may be wires for transmitting signals, which are transmitted to the pad part PAD from the flexible circuit board (or flexible film) CB and the printed circuit board 160 (see FIG. 1), to the pixel driving circuit PD of the display area AA. For example, the plurality of second connection wires 122 may be electrically connected to the plurality of pad electrodes PE to receive signals from the flexible circuit board (or flexible film) CB and the printed circuit board.

For example, the plurality of second connection wires 122 may extend from the pad part PAD toward the display area AA to transmit signals to the wires in the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d.

The second connection wire 122 may be formed to correspond to the first connection wire 121. The first connection wire 121 and the second connection wire 122 may be formed or deposited in the same step of the manufacturing process, except for the difference in where they are arranged (the first connection wire 121 is arranged in the display area, and the second connection wire 122 is arranged in the bending area and the second non-display area).

A plurality of second-first connection wires 122a may be arranged on the second protective layer 113b. The second-first connection wires 122a may correspond to the first-first connection wires 121a. The term “corresponding” means that the items are made of the same material in the same manufacturing process, have the same intrinsic resistance, and have the same thickness, width, cross-sectional area, etc. However, the items may not be formed to have the same length. The plurality of second-first connection wires 122a may extend from the second non-display area NA2 to the bending area BA and the first non-display area NA1. The plurality of second-first connection wire 122a may transmit signals, which are transmitted to the pad part PAD from the flexible circuit board (or flexible film) CB and the printed circuit board, to the pixel driving circuit PD of the display area AA.

A plurality of first-second connection wires 122b may be arranged on the third protective layer 114. The second-second connection wires 122b may correspond to the first-second connection wires 121b. The plurality of second-second connection wires 122b may be arranged on the second non-display area NA2. The second-second connection wires 122b may be electrically connected to the second-first connection wires 122a via contact holes in the third protective layer 114. Thus, the signals from the flexible circuit board (or flexible film) (CB) and the printed circuit board may be transmitted to the second-first connection wires 122a via the second-second connection wires 122b.

A plurality of second-third connection wires 122c may be arranged on the first insulating layer 115a. The second-third connection wires 122c may correspond to the first-third connection wires 121c. The second-third connection wires 122c may be arranged on the second non-display area NA2. The second-third connection wires 122c may be electrically connected to the second-second connection wires 122b via contact holes in the first insulating layer 115a. Thus, signals from the flexible circuit board (or flexible film) (CB) and the printed circuit board may be transmitted to the second-first connection wires 122a via the second-third connection wires 122c and the second-second connection wires 122b.

A plurality of second-fourth connection wires 122d may be arranged on the second insulating layer 115b. The second-fourth connection wires 122d may correspond to the first-fourth connection wires 121d. The second-fourth connection wires 122d may be arranged on the second non-display area NA2. The second-fourth connection wires 122d may be electrically connected to the second-third connection wires 122c via contact holes in the second organic insulating layer 115b. Thus, signals from the flexible film (FF) and the printed circuit board may be transmitted to the second-first connection wires 122a via the second-fourth connection wires 122d, the second-third connection wires 122c, and the second-second connection wire 122b.

The plurality of first connection wires 121 and the plurality of second connection wires 122 may be formed of any one of a conductive material having excellent ductility or various conductive materials used in the display area AA. For example, the second connection wire 122, a portion of which is arranged in the bending area BA, may be made of a conductive material having excellent ductility, such as gold (Au), silver (Ag), or aluminum (Al), but embodiments of the present disclosure are not limited thereto. For example, the plurality of first connection wires 121 and the plurality of second connection wires 122 may be formed of molybdenum (Mo), chromium (Cr), titanium (Ti), nickel (Ni), neodymium (Nd), copper (Cu), aluminum (Al), and alloys of silver (Ag) and magnesium (Mg), or alloys thereof, but embodiments of the present disclosure are not limited thereto.

A third insulating layer 115c may be arranged on the plurality of first connection wires 121 and the plurality of second connection wires 122. The third insulating layer 115c may be arranged in the remaining area except for the bending area BA, but embodiments of the present disclosure are not limited thereto. The third insulating layer 115c may be arranged in the display area AA, the first non-display area NA1, and the second non-display area NA2. A portion of the third insulating layer 115c in the bending area BA may be removed. The third insulating layer 115c may be formed of an organic insulating material, but embodiments of the present disclosure are not limited thereto. For example, the third insulating layer 115c may be formed of a photo resist, polyimide (PI), or photo acryl-based material, but embodiments of the present disclosure are not limited thereto.

In the display area AA, a plurality of banks BNK may be arranged on the third insulating layer 115c. The plurality of banks BNK may be arranged to overlap each of the plurality of sub-pixels. One or more light-emitting elements ED of the same type may be arranged in the upper portion of each of the plurality of banks BNK.

In the display area AA, the plurality of signal wires TL may be arranged on the third insulating layer 115c. The plurality of signal wire TLs may be arranged in an area between the plurality of banks BNK. For example, the plurality of signal wires TL may be arranged adjacent to any one of the plurality of banks BNK.

A plurality of contact electrodes CCE may be arranged on the third insulating layer 115c in the display area AA. The plurality of contact electrodes CCE may supply the cathode voltage from the pixel driving circuit PD to the second electrode CE2.

The first electrode CE1 may be arranged on the bank BNK. For example, the first electrode CE1 may be arranged extending from the adjacent signal wire TL toward the upper portion of the bank BNK. The first electrode CE1 may be arranged on the top surface of the bank BNK and the side surface of the bank BNK. For example, the first electrode CE1 may be arranged extending from the signal wire TL on the top surface of the third insulating layer 115c to the side surface of the bank BNK and to the top surface of the bank BNK. The first electrode CE, the signal wire TL, and the pad electrode PE may be formed or deposited in the same step of the manufacturing process, except for differences in their arranged positions. The pad electrode PE may correspond to the first electrode CE or the signal wire TL.

In the display area AA, a first optical layer 117a may be arranged around the plurality of light-emitting elements ED. For example, the first optical layer 117a may be arranged surrounding the plurality of light-emitting elements ED. For example, the first optical layer 117a may be arranged to cover the plurality of light-emitting elements ED and banks BNK in a plurality of sub-pixel regions. For example, the first optical layer 117a may cover between the bank BNK, a portion of the passivation layer 116, and the plurality of light-emitting elements ED. The first optical layer 117a may be arranged between or cover the plurality of light-emitting elements ED included in one pixel PX and between the plurality of banks BNK. For example, the first optical layer 117a may extend in the first direction (for example, the X-axis direction), and may be spaced apart in the second direction (for example, the Y-axis direction). For example, the first optical layer 117a may be arranged between the passivation layer 116 and the second electrode CE2 to surround the side portions of the light-emitting element ED and the bank BNK, but embodiments of the present disclosure are not limited thereto. For example, the first optical layer 117a may be a diffusion layer, a sidewall diffusion layer, or the like, but embodiments of the present disclosure are not limited thereto.

The first optical layer 117a may include an organic insulating material in which fine particles are dispersed, but embodiments of the present disclosure are not limited thereto. For example, the first optical layer 117a may be formed of siloxane in which fine metal particles such as titanium dioxide (TiO₂) particles are dispersed, but embodiments of the present disclosure are not limited thereto. Light from the plurality of light-emitting elements ED may be scattered by the fine particles dispersed in the first optical layer 117a and emitted to the outside of the display apparatus 1000. This may ensure that the first optical layer 117a improves the extraction efficiency of light emitted from the plurality of light-emitting elements ED.

For example, the first optical layer 117a may be arranged in each of the plurality of pixels PX, or may be arranged together in some of the pixels PX arranged in the same row, but embodiments of the present disclosure are not limited thereto. For example, the first optical layer 117a may be arranged in each of the plurality of pixels PX, or one first optical layer 117a may be shared by the plurality of pixels PX. For another example, each of the plurality of sub-pixels may separately include the first optical layer 117a, but embodiments of the present disclosure are not limited thereto.

Referring to the above plan views, the third optical layer 117c may be arranged between the first optical layers 117a. The third optical layer 117c may be arranged on the passivation layer 116 in the display area AA. For example, the third optical layer 117c may be arranged around the first optical layer 117a. For example, the third optical layer 117c may be arranged to surround the first optical layer 117a. For example, the third optical layer 117c may be in contact with the side surface of the first optical layer 117a. For example, the third optical layer 117c may be arranged in an area between the plurality of pixels PX. However, embodiments of the present disclosure are not limited thereto. For example, the third optical layer 117c may be a diffusion layer, a diffusion layer window, or a window diffusion layer, but embodiments of the present disclosure are not limited thereto.

The third insulating layer 117c may be formed of an organic insulating material, but embodiments of the present disclosure are not limited thereto. The third optical layer 117c may be formed of the same material as the first optical layer 117a, but embodiments of the present disclosure are not limited thereto. For example, the first optical layer 117a may include fine particles, and the third optical layer 117c may not include fine particles. For example, the third optical layer 117c may be made of siloxane, but embodiments of the present disclosure are not limited thereto.

For example, the thickness of the first optical layer 117a may be less than the thickness of the third optical layer 117c, but embodiments of the present disclosure are not limited thereto. Accordingly, when viewed from a plan, the region in which the first optical layer 117a is arranged may include a concave portion recessed inwardly from the upper surface of the third optical layer 117c.

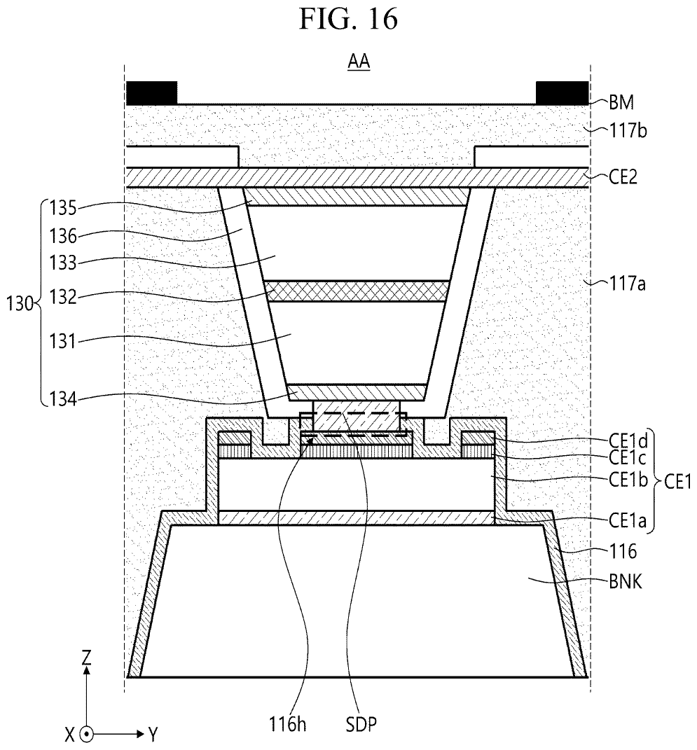

According to one or more aspects of the present disclosure, the second electrode CE2 may be arranged on the first optical layer 117a and the third optical layer 117c. For example, the second electrode CE2 may be electrically connected to the plurality of contact electrodes CCE via contact holes in the third optical layer 117c. For example, the second electrode CE2 may be arranged on the plurality of light-emitting elements ED. For example, the second electrode CE2 may include a transparent conductive oxide such as indium tin oxide (ITO) or indium zinc oxide (IZO), but embodiments of the present disclosure are not limited thereto. For example, the second electrode CE2 may be arranged in contact with a cathode electrode (e.g., 135 in FIG. 16). For example, the second electrode CE2 may overlap the first optical layer 117a. For example, the second electrode CE2 may cover the outer plane of the first optical layer 117a.

The second electrode CE2 may extend continuously in a first direction (e.g., the X-axis direction) of the substrate 110. Accordingly, it may be commonly connected to the plurality of pixels PX arranged in the first direction (e.g., X-axis direction) of the substrate 110. For example, the second electrode CE2 may be commonly connected to the plurality of pixels PX.

According to one or more aspects of the present disclosure, the second electrode CE2 may extend continuously on the first optical layer 117a, the third optical layer 117c, and the light-emitting element ED. The region in which the first optical layer 117a is arranged may include a concave portion that is recessed inwardly from the upper surface of the third optical layer 117c. Accordingly, the first portion of the second electrode CE2 arranged on the first optical layer 117a is arranged along the concave portion, so that it may be located at a lower position than the second portion of the second electrode CE2 arranged on the third optical layer 117c.

A second optical layer 117b may be arranged on the second electrode CE2. The second optical layer 117b may be arranged to overlap the plurality of light-emitting elements ED and the first optical layer 117a. The second optical layer 117b may be arranged on the upper portion of the second electrode CE2 and the plurality of light-emitting elements ED, which may improve the mura that may occur in some of the plurality of light-emitting elements ED. For example, when a plurality of light-emitting elements ED are transferred to the substrate 110 of the display apparatus 1000, regions of non-uniform spacing between the plurality of light-emitting elements ED may occur due to process variations. If the spacing between the plurality of light-emitting elements ED is uneven, the light emission area of each of the plurality of light-emitting elements ED may be arranged uneven, resulting in the mura visible to the user. Since the second optical layer 117b may be formed to diffuse light uniformly onto the upper portion of the plurality of light-emitting elements ED, it is possible to reduce the light emitted from some of the light-emitting elements ED from being visually recognized as the mura. Therefore, with the second optical layer 117b, the light emitted from the plurality of light-emitting elements ED is uniformly diffused and extracted to the outside of the display apparatus 1000, which may improve the luminance uniformity of the display apparatus 1000.

The second optical layer 117b may be formed of an organic insulating material in which fine particles are dispersed, but embodiments of the present disclosure are not limited thereto. For example, the second optical layer 117b may be formed of siloxane dispersed with fine metal particles, such as titanium dioxide (TiO₂) particles, but embodiments of the present disclosure are not limited thereto. For example, the second optical layer 117b may be formed of the same material as the first optical layer 117a, but embodiments of the present disclosure are not limited thereto. For example, the second optical layer 117b may be a diffusion layer, a top surface diffusion layer, or the like, but embodiments of the present disclosure are not limited thereto.

According to one or more aspects of the present disclosure, light from the plurality of light-emitting elements ED may be scattered by fine particles dispersed in the second optical layer 117b and emitted to the outside of the display apparatus 1000. The second optical layer 117b may further improve luminance uniformity of the display apparatus 1000 by uniformly mixing light emitted from the plurality of light-emitting elements ED. Further, light scattered from the plurality of fine particles may improve the light extraction efficiency of the display apparatus 1000, thereby enabling the display apparatus 1000 to be driven at low power.

A black matrix BM may be arranged on the second electrode CE2, the first optical layer 117a, the third optical layer 117c, and the second optical layer 117b in the display area AA. For example, the black matrix BM may fill the contact holes in the third optical layer 117c. The black matrix BM may be configured to cover the display area AA, thereby reducing the color mixing of light from the plurality of sub-pixels and reflection of external light. For example, the black matrix BM may also be arranged within the contact holes in which the second electrode CE2 and the contact electrode CCE are connected, which may prevent light leakage between the plurality of adjacent sub-pixels.

For example, the black matrix BM may be formed of an opaque material, but embodiments of the present disclosure are not limited thereto. For example, the black matrix BM may be a black pigment or an organic insulating material to which a black dye has been added, but embodiments of the present disclosure are not limited thereto.

In the display area AA, a cover layer 118 may be arranged on the black matrix BM. The cover layer 118 may protect the components under the cover layer 118. For example, the cover layer 118 may be formed of an organic material, but embodiments of the present disclosure are not limited thereto. For example, the cover layer 118 may be formed of a photo resist, polyimide (PI), or photo acryl-based material, but embodiments of the present disclosure are not limited thereto. For example, the cover layer 118 may be an overcoating layer or an insulating layer, but embodiments of the present disclosure are not limited thereto.

A polarizing layer 293 may be arranged on the cover layer 118 via the first adhesive layer 291. A cover member 120 may be arranged on the polarizing layer 293 via a second adhesive layer 295. For example, the first adhesive layer 291 and the second adhesive layer 295 may include an optically cleared adhesive (OCA), an optically cleared resin (OCR), or a pressure sensitive adhesive (PSA), but embodiments of the present disclosure are not limited thereto.

According to one or more aspects of the present disclosure, the plurality of pad electrodes PE may be arranged on the third insulating layer 115c in the second non-display area NA2. The pad electrode PE may correspond to the first electrode CE or the signal wire TL. For example, at least a portion of the plurality of pad electrodes PE may be exposed from the passivation layer 116. For example, the plurality of pad electrodes PE may be electrically connected to the second-fourth connection wires 122d via contact holes in the third insulating layer 115c.

An adhesive layer ACF may be arranged on the plurality of pad electrode PE. The adhesive layer ACF may be an adhesive layer in which conductive balls are dispersed in an insulating material, but embodiments of the present disclosure are not limited thereto. When heat or pressure is applied to the adhesive layer ACF, the conductive balls may become electrically connected and have conductive properties at the points where heat or pressure is applied, exhibiting the conductive properties. The adhesive layer ACF may be arranged between the plurality of pad electrodes PE and the flexible circuit board (or flexible film) CB to attach or bond the flexible circuit board (or flexible film) CB to the plurality of pad electrodes PE. For example, the adhesive layer ACF may be an anisotropic conductive film (ACF), but embodiments of the present disclosure are not limited thereto.

The flexible circuit board (or flexible film) CB may be arranged on the adhesive layer ACF. The flexible circuit board (or flexible film) CB may be electrically connected to the plurality of pad electrodes PE through the adhesive layer ACF. Thus, signals output from the flexible circuit board (or flexible film) CB and the printed circuit board may be transmitted to the pixel driving circuit PD of the display area AA via the plurality of pad electrodes PE, the second-fourth connection wire 122d, the second-third connection wire 122c, the second-second connection wire 122b, and the second-first connection wire 122a.

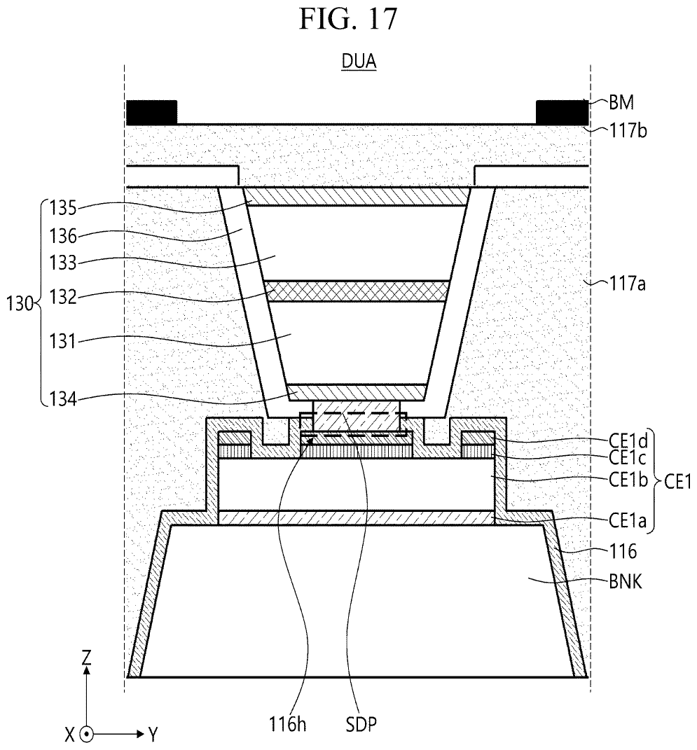

FIG. 16 is a cross-sectional view illustrating the display apparatus according to an embodiment of the present disclosure. FIG. 17 is a cross-sectional view illustrating the display apparatus according to an embodiment of the present disclosure.

FIG. 16 is a cross-sectional view illustrating a sub-pixel including a light-emitting element arranged in the display area. FIG. 17 is a cross-sectional view illustrating a sub-pixel including a light-emitting element arranged in the non-display area. The same reference numbers are assigned to substantially the same configuration between the cross-sectional views embodiments, and repeated descriptions are omitted.

Referring to FIGS. 16 and 17, the first electrode CE1 may be composed of a plurality of conductive layers. For example, the first electrode CE1 may include a first conductive layer Ce1a, a second conductive layer CE1b, a third conductive layer CE1c, and a fourth conductive layer CE1d, but embodiments of the present disclosure are not limited thereto.

The first conductive layer CE1a may be arranged on the bank BNK. The second conductive layer CE1b may be arranged on the first conductive layer CE1a. The third conductive layer CE1c may be arranged on the second conductive layer CE1b. The fourth conductive layer CE1d may be arranged on the third conductive layer CE1c. For example, each of the first conductive layer CE1a, second conductive layer CE1b, third conductive layer CE1c, and fourth conductive layer CE1d may be formed of Titanium (Ti), Molybdenum (Mo), Aluminum (Al), or Titanium (Ti) and Indium Tin Oxide (ITO), but embodiments of the present disclosure are not limited thereto.

According to one or more aspects of the present disclosure, among the plurality of conductive layers constituting the first electrode CE1, some conductive layers having good reflection efficiency may be configured as alignment keys and/or reflectors for aligning the light-emitting element ED. For example, the second conductive layer CE1b of the plurality of conductive layers of the first electrode CE1 may include a reflective material. For example, the second conductive layer CE1b may include aluminum (Al), but embodiments of the present disclosure are not limited thereto. In this way, the second conductive layer CE1b may be configured as a reflector. Further, the high reflective efficiency of the second conductive layer CE1b may facilitate easy identification during the manufacturing process, allowing for alignment of the light-emitting element ED or its transfer position relative to the second conductive layer CE1b.

For example, in order to configure the second conductive layer CE1b as a reflector, the third conductive layer CE1c and the fourth conductive layer CE1d covering the second conductive layer CE1b may be partially removed or etched away. For example, portions of the third conductive layer CE1c and fourth conductive layer CE1d arranged on the bank BNK may be partially removed or etched to expose the top surface of the second conductive layer CE1b. For example, the third conductive layer CE1c and the fourth conductive layer CE1d, except for the center portion and the border portions (or edge portions) of these layers where a solder pattern SDP is placed, may be removed. For example, the border portion (or edge portion) of each of the third conductive layer CE1c made of titanium (Ti) and the fourth conductive layer CE1d made of indium tin oxide (ITO) may not be etched. Accordingly, the other conductive layers of the first electrode CE1 may be prevented from being corroded by the TMAH (TetraMethylAmmoniumHydroxide) solution used in the masking process of the first electrode CE1.

According to one or more aspects of the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially formed or deposited and then patterned by a photolithography process and an etching process, but embodiments of the present disclosure are not limited thereto.

According to one or more aspects of the present disclosure, the signal line TL, the contact electrode CCE, and the pad electrode PE arranged in the same layer as the first electrode CE1 may be formed of a multi-layer of a conductive material, but embodiments of the present disclosure are not limited thereto. For example, the signal line TL, the contact electrode CCE, and the pad electrode PE may be made of a multi-layer of indium tin oxide (ITO)/titanium (Ti)/aluminum (Al)/titanium (Ti), but embodiments of the present disclosure are not limited thereto.

According to one or more aspects of the present disclosure, the solder pattern SDP may be arranged on the first electrode CE in each of the plurality of sub-pixels. The solder pattern SDP may bond the light-emitting element ED to the first electrode CE1. The first electrode CE1 and the light-emitting element ED may be electrically connected each other through eutectic bonding using the solder pattern SDP, but embodiments of the present disclosure are not limited thereto. For example, the first electrode CE1 and the anode electrode 134 of the light-emitting element ED may be electrically connected through eutectic bonding by the solder pattern SDP, but embodiments of the present disclosure are not limited thereto. For example, if the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. The eutectic bonding may allow the light-emitting element ED to be bonded to the solder pattern SDP and the first electrode CE1 without a separate adhesives. For example, the solder pattern SDP may be formed of indium (In), tin (Sn), or an alloy thereof, but embodiments of the present disclosure are not limited thereto. For example, the solder pattern SDP may be a pattern, pattern layer, bonding pad, or binding pad, but embodiments of the present disclosure are not limited thereto.

According to one or more aspects of the present disclosure, the passivation layer 116 may be arranged on the plurality of signal wires TL, the plurality of first electrodes CE1, the plurality of contact electrodes CCE, and the third insulating layer 115c. For example, the passivation layer 116 may be arranged in the display area AA, the first non-display area NA1, and the second non-display area NA2. A portion of the passivation layer 116 arranged in the bending area BA may be removed. A portion of the passivation layer 116 covering the plurality of pad electrodes PE in the second non-display area NA2 may be removed. The passivation layer 116 may be arranged to cover the remaining areas except the area in which the bending area BA, the plurality of pad electrodes PE, and the solder pattern SDP are arranged, thereby reducing moisture or impurities to penetrate into the light-emitting element ED. For example, the passivation layer 116 may be formed of a single or multiple layers of silicon oxide (SiOx) or silicon nitride (SiNx), but embodiments of the present disclosure are not limited thereto. For example, the passivation layer 116 may be a protective layer, an insulating layer, or the like, but embodiments of the present disclosure are not limited thereto. For example, the passivation layer 116 may include a hole 116h that expose the solder pattern SDP.

The light-emitting element ED may be arranged on the solder pattern SDP in each of the plurality of sub-pixels. The first light-emitting element 130 may be arranged in the first sub-pixel SP1. The second light-emitting element 140 may be arranged in the second sub-pixel SP2. The third light-emitting element 150 may be arranged in the third sub-pixel SP3.

The light-emitting element ED may be formed on a silicon wafer by a method such as metal organic vapor deposition (MOCVD), chemical vapor deposition (CVD), plasma-enhanced chemical vapor deposition (PECVD), molecular beam growth (MBE), hydride vapor deposition (HVPE), or sputtering, but embodiments of the present disclosure are not limited thereto.

The first light-emitting element 130 may include the anode electrode 134, a first semiconductor layer 131, an active layer 132, a second semiconductor layer 133, the cathode electrode 135, and an encapsulation film 136, but embodiments of the present disclosure are not limited thereto. For example, the encapsulation film 136 may not be included in the first light-emitting element 130.

The first semiconductor layer 131 may be arranged on the solder pattern SDP. The second semiconductor layer 133 may be arranged on the first semiconductor layer 131.

For example, one of the first semiconductor layer 131 and the second semiconductor layer 133 may be implemented as a compound semiconductor, such as a III-V group, II-VI group, or the like, and may be doped with impurities (or dopants). For example, one of the first semiconductor layer 131 and the second semiconductor layer 133 may be a semiconductor layer doped with n-type impurities, and the other may be a semiconductor layer doped with p-type impurities, but embodiments of the present disclosure are not limited thereto. For example, one or more of the first semiconductor layer 131 and the second semiconductor layer 133 may be a layer doped with n-type or p-type impurities in a material such as gallium nitride (GaN), gallium phosphide (GaP), aluminum gallium indium phosphide (AlGaInP), indium gallium nitride (AlGaN), aluminum indium nitride (AlInN), aluminum gallium nitride (AlInGaN), aluminum gallium nitride (AlGaAs), aluminum gallium arsenide (AlGaAs), or gallium arsenide (GaAs), but embodiments of the present disclosure are not limited thereto. For example, the n-type impurity may be silicon (Si), germanium (Ge), selenium (Se), carbon (C), tellurium (Te), or tin (Sn), but embodiments of the present disclosure are not limited thereto. For example, the p-type impurity may be magnesium (Mg), zinc (Zn), calcium (Ca), strontium (Sr), barium (Ba), or beryllium (Be), but embodiments of the present disclosure are not limited thereto.

For example, the first semiconductor layer 131 and the second semiconductor layer 133 may be a nitride semiconductor containing n-type impurities and a nitride semiconductor containing p-type impurities, respectively, but embodiments of the present disclosure are not limited thereto. For example, the first semiconductor layer 131 may be a nitride semiconductor containing p-type impurities, and the second semiconductor layer 133 may be a nitride semiconductor containing n-type impurities, but embodiments of the present disclosure are not limited thereto.

The active layer 132 may be arranged between the first semiconductor layer 131 and the second semiconductor layer 133. The active layer 132 may emit light by receiving holes and electrons from the first semiconductor layer 131 and the second semiconductor layer 133. For example, the active layer 132 may be composed of one of a single well structure, a multi-well structure, a single quantum well structure, a multi-quantum well (MQW) structure, a quantum dot structure, and a quantum line structure, but embodiments of the present disclosure are not limited thereto. For example, the active layer 132 may made of indium gallium nitride (InGaN) or gallium nitride (GaN), but embodiments of the present disclosure are not limited thereto.

For another example, the active layer 132 may include a multi quantum well (MQW) structure having a well layer and a barrier layer with a higher band gap than the well layer. For example, the active layer 132 may made of InGaN as a well layer and AlGaN layer as a barrier layer, but embodiments of the present disclosure are not limited thereto.

The anode electrode 134 may be arranged between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 via the signal wire TL, the first electrode CE1, and the anode electrode 134. For example, the anode electrode 134 may made of a conductive material that is eutectically bondable with the solder pattern SDP, but embodiments of the present disclosure are not limited thereto. For example, the anode electrode 134 may made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof, but embodiments of the present disclosure are not limited thereto.

The cathode electrode 135 may be arranged on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 via the contact electrode CCE, the second electrode CE2, and the cathode electrode 135. The cathode electrode 135 may made of a transparent conductive material to allow light emitted from the ED to be directed to the upper portion of the ED, but embodiments of the present disclosure are not limited thereto. For example, the cathode electrode 135 may made of a material such as Indium Tin Oxide (ITO), Indium Zinc Oxide (IZO), or Indium Gallium Zinc Oxide (IGZO), but embodiments of the present disclosure are not limited thereto.

The encapsulation film 136 may be arranged on at least a portion of the first semiconductor layer 131, the active layer 132, the second semiconductor layer 133, the anode electrode 134, and the cathode electrode 135. For example, the encapsulation film 136 may surround at least a portion of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be arranged on a side surface of the first semiconductor layer 131, a side surface of the active layer 132, and a side surface of the second semiconductor layer 133.

For example, the encapsulation film 136 may be arranged on at least portions of the anode electrode 134 and the cathode electrode 135, such as an edge portion (or one side) of the anode electrode 134 and an edge portion (or one side) of the cathode electrode 135. At least a portion of the anode electrode 134 may be exposed from the encapsulation film 136, allowing the anode electrode 134 and the solder pattern SDP to be connected. For example, at least a portion of the cathode electrode 135 may be exposed from the encapsulation film 136, allowing the cathode electrode 135 and the second electrode CE2 to be connected. For example, the encapsulation film 136 may made of an insulating material such as silicon nitride (SiNx) or silicon oxide (SiOx), but embodiments of the present disclosure are not limited thereto.

For another example, the encapsulation film 136 may have a structure in which a reflective material is dispersed in a resin layer, but embodiments of the present disclosure are not limited thereto. For example, the encapsulation film 136 may be fabricated as a reflector having various structures, but embodiments of the present disclosure are not limited thereto. Light exciting from the active layer 132 is reflected upward by the encapsulation film 136 to improve light extraction efficiency. For example, the encapsulation film 136 may be a reflective layer, but embodiments of the present disclosure are not limited thereto.

Although the light-emitting element ED is described herein as having vertical structure, embodiments of the present disclosure are not limited thereto. For example, the light-emitting element ED may have a lateral structure or a flip chip structure.

While the first light-emitting element 130 has been described, the second light-emitting element 140 and third light-emitting element 150 may have substantially the same structure as the first light-emitting element 130. For example, the second light-emitting element 140 and the third light-emitting element 150 may be substantially the same as the first light-emitting element 130 having the first semiconductor layer 131, the active layer 132, the second semiconductor layer 133, the anode electrode 134, the cathode electrode 135, and the encapsulating film 136, but embodiments of the present disclosure are not limited thereto. In addition, the difference between the light-emitting element of the sub-pixel arranged in the non-display area shown in FIG. 17 and the light-emitting element of the sub-pixel arranged in the display area shown in FIG. 16 is that the second electrode CE2 is not provided above the cathode electrode 135 of the light-emitting element of the sub-pixel arranged in the non-display area.

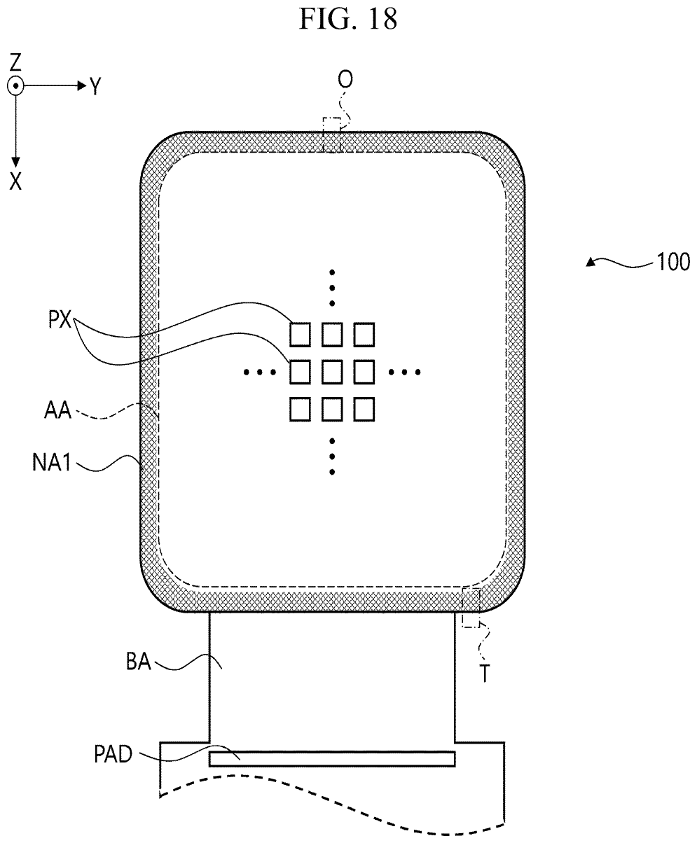

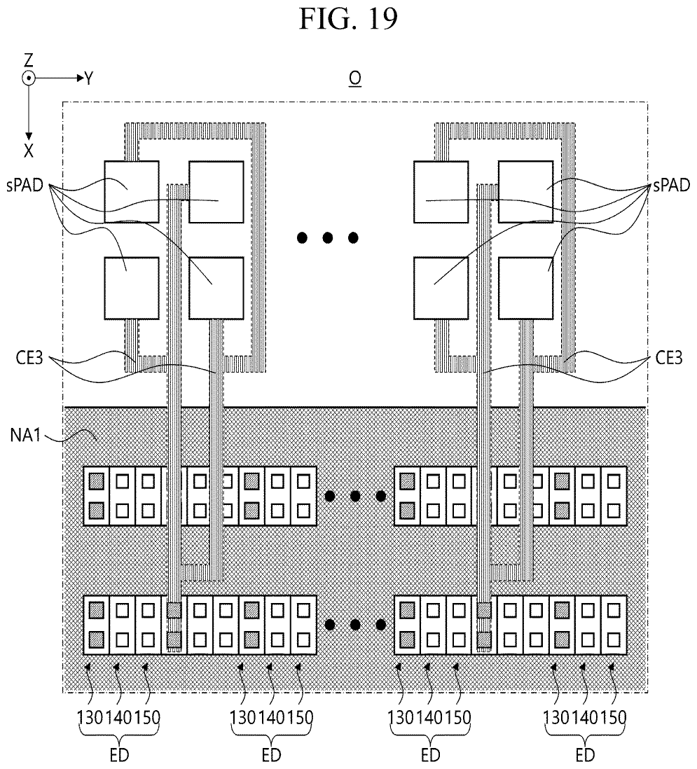

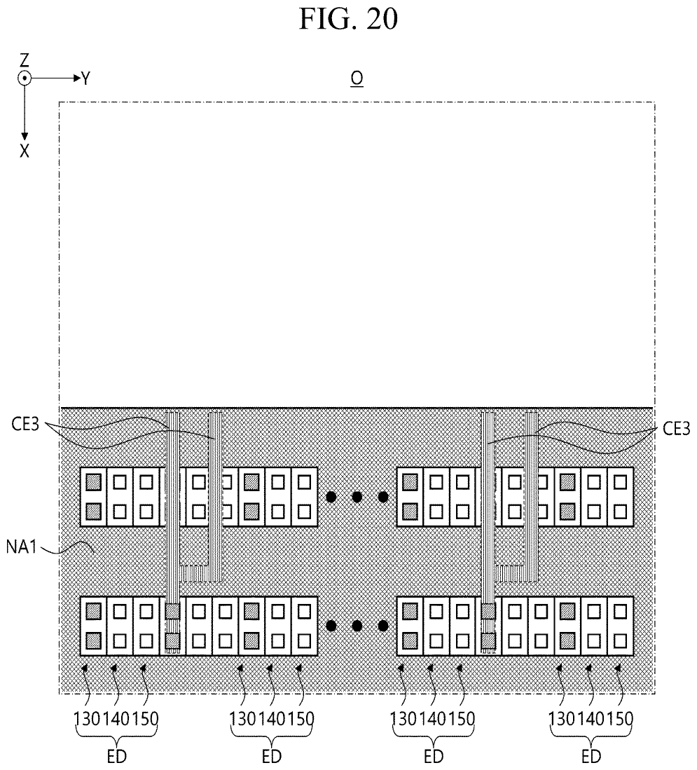

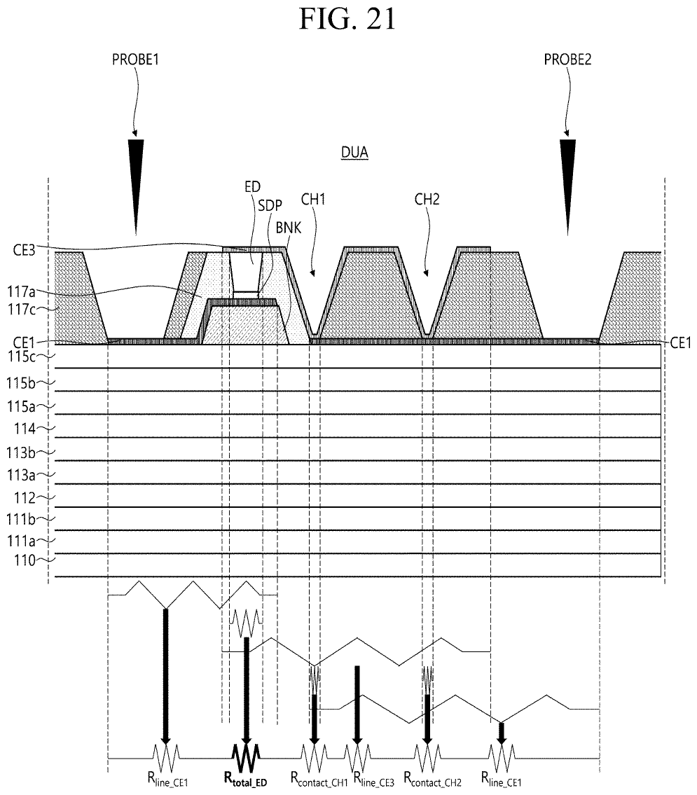

FIG. 18 is a plan view illustrating the display apparatus according to an embodiment of the present disclosure. FIGS. 19 and 20 are partially enlarged views illustrating an enlarged portion O of FIG. 18. FIG. 21 is a cross-sectional view illustrating the display apparatus according to an embodiment of the present disclosure.

The third electrode CE3 of the present disclosure may be separately arranged on the dummy light-emitting element so as to obtain the measurement which is substantially the same as or similar to the physical property value of the light-emitting element arranged in the display area, but is not limited thereto. Both the second electrode arranged in the display area and the third electrode CE3 arranged in the first non-display area NA1 may be arranged on substantially the same light-emitting element. Accordingly, by measuring the physical property value of the dummy light-emitting element, the physical property value of the light-emitting element arranged in the display area may be confirmed.

Referring to FIG. 19, in an embodiment, during the measurement process, third electrodes CE3 are arranged on the dummy light-emitting elements 130, 140, and 150 arranged in the first non-display area NA1 and a separate pad sPAD is connected to these elements to measure the resistance of the dummy light-emitting elements. Referring to FIG. 20, the separate pad sPAD is removed after the measurement process.

Referring to FIG. 21, the first non-display area may include the dummy area DUA having the TEG structure. The dummy area DUA may include a first electrode CE1 in contact with a first probe PROBE1, a dummy light-emitting element ED electrically connected to the first electrode, a third electrode CE3 electrically connected to the dummy light-emitting element ED, and a first electrode CE1 connected to the third electrode CE3. The first electrode CE1, which is electrically connected to the third electrode CE3, may be in contact with a second probe PROBE2.

In one embodiment, the solder pattern SDP may be arranged between a bank BNK and the dummy light-emitting element ED. The first electrode CE1 may be arranged between the bank BNK and the solder pattern SDP. The first electrode CE1 and the dummy light-emitting element ED may be electrically connected through eutectic bonding by the solder pattern SDP, but embodiments of the present disclosure are not limited thereto. The eutectic bonding may allow the dummy light-emitting element ED to be bonded to the solder pattern SDP and the first electrode CE1 without a separate adhesive.

During the measurement process, the resistance R_{total_ED} of the dummy light-emitting element ED may be measured by utilizing the TEG structure. Since the physical property values of the dummy light-emitting element is essentially the same as or similar to those of the light-emitting element arranged in the display area, measuring the resistance of the dummy light-emitting element ED is equivalent to measuring the resistance of the light-emitting element located in the display area. The resistance R_{total_ED} of the dummy light-emitting element ED may then be measured. However, due to the limitation of the physical structure, the portion where the first probe PROBE1 and the second probe PROBE2 are in contact may be a hole through which the first electrode CE1 is exposed. Therefore, in addition to the resistance R_{total_ED} of the dummy light-emitting element ED to be measured in this process, the line resistance R_{line_CE1} of the first electrode CE1, the line resistance R_{line_CE3} of the third electrode CE3, the contact resistance R_{contact_CH1} of the first electrode CE1 and the third electrode CE3 in the first contact hole CH1, and the contact resistance R_{contact_CH2} of the first electrode CE1 and the third electrode CE3 in the second contact hole CH2 may be further measured.

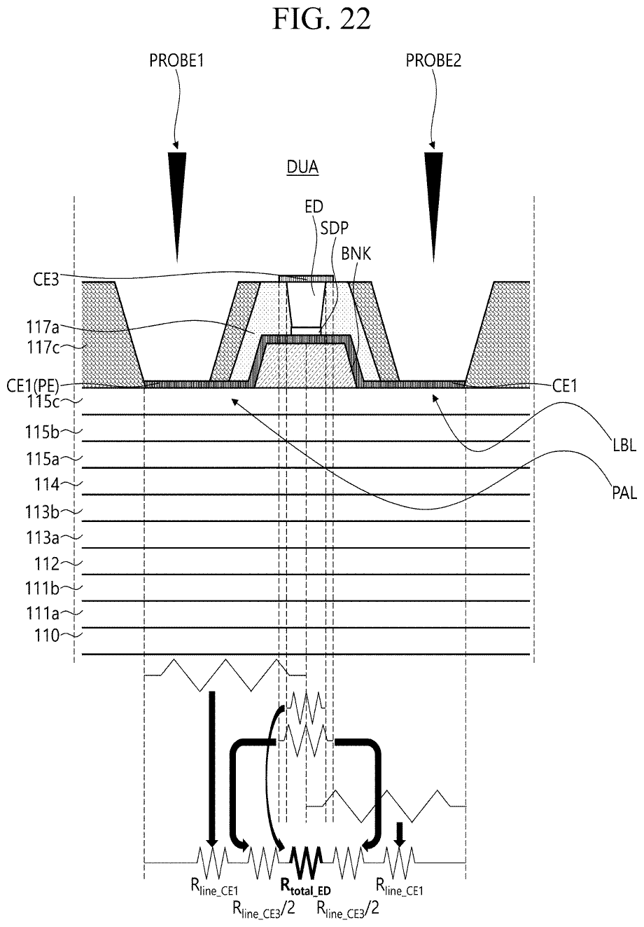

FIG. 22 is a cross-sectional view illustrating a display apparatus according to another embodiment of the present disclosure.

Referring to FIG. 22, the display apparatus according to another embodiment of the present disclosure may include a loopback wire LBL and a pad connecting wire PAL. The loopback wire LBL may expose a first electrode CE1. The pad connecting wire PAL may include a first electrode CE1 (PE). While the reference numeral “PE” has been used to denote the pad electrode in the foregoing figures, since the pad electrode and the first electrode CE1 correspond to each other for the purpose of the manufacturing process, the first electrode is considered to have substantially the same configuration as the pad electrode for the purpose of the description. In the foregoing figures, PE has been referred to as denoted as the pad electrode in the sense of being connected to the pad part PAD, and in this figure, the first electrode CE1 and the pad electrode PE may be made of materials having substantially the same intrinsic resistance. However, this is not limited to that.

In one embodiment, a solder pattern SDP may be arranged between a bank BNK and a dummy light-emitting element ED. The first electrode CE1 may be arranged between the bank BNK and the solder pattern SDP. The first electrode CE1 and the dummy light-emitting element ED may be electrically connected through eutectic bonding by the solder pattern SDP, but embodiments of the present disclosure are not limited thereto. The eutectic bonding may allow the dummy light-emitting element ED to be bonded to the solder pattern SDP and the first electrode CE1 without a separate adhesive.

The display apparatus according to an embodiment of the present disclosure may include a loopback wire LBL and a pad connection wire PAL having the same intrinsic resistance during a measurement process. The intrinsic resistance may be a unique property of a material as a value of resistance per unit length and per unit cross-sectional area. During the measurement process, the first electrode resistance R_{line_CE1} of the loopback wire LBL may be the same as the first electrode resistance R_{line_CE1} of the pad connection wire PAL when the loopback wire LBL and the pad connection wire PAL having the same intrinsic resistance are formed to have the same length. When the center of a third electrode CE3 located on the dummy light-emitting element ED is arranged to be equal to the center of the dummy light-emitting element ED, it can be considered that the third electrode resistance R_{line_CE3} is divided equally on both sides on the basis of the resistance R_{total_ED} of the dummy light-emitting element being measured (R_{line_CE3}/2=R_{line_CE3}/2).

Accordingly, the resistances measured by the first probe PROBE1 and the second probe PROBE2 may be symmetrical based on the dummy light-emitting element resistance R_{total_ED} to be measured. Since the resistances are symmetrical, additional computations for calculating the resistance of the dummy light-emitting element ED after the measurement may be reduced. Therefore, according to the display apparatus of the embodiment of the present disclosure, the derivation of the resistance R_{total_ED} of the dummy light-emitting element ED to be measured may be simplified by arranging the loopback wire LBL and the pad connection wire PAL having the same length, width, thickness, and cross-sectional area during the measurement process.

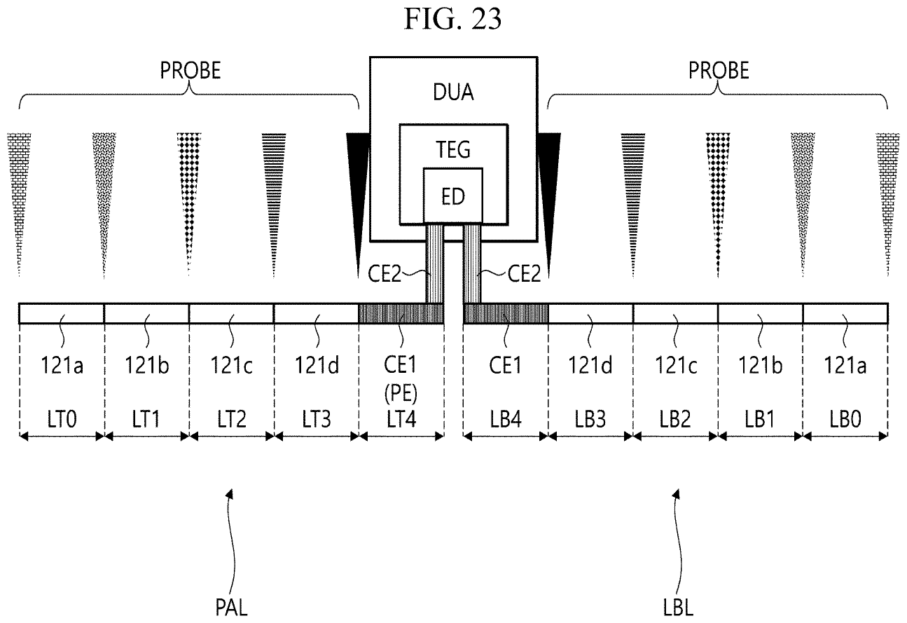

FIGS. 23 to 30 are diagrams illustrating the display apparatus according to embodiments of the present disclosure.

Referring to FIGS. 23 to 30, the type of connection wires included in each of the loopback wire LBL and the pad connection wire PAL may vary depending on the embodiments. As described above, the first connection wire 121 and the second connection wire 122 may be formed in the same step of the manufacturing process, except for the differences in their arranged positions (the first connection wire 121 is arranged in the display area, and the second connection wire 122 is arranged in the bending area and the second non-display area). In addition, the first electrode CE and the pad electrode PE may also be formed in the same step of the manufacturing process, except for the differences in their arranged positions. Therefore, unlike the illustration, the pad connection wire PAL may include the second connection wire 122 instead of the first connection wire 121. Alternatively, instead of the first connection wire 121, e.g., first connection wires 121a, 121b, 121c, 121d, a corresponding second connection wire 122, e.g., second connection wire 122a, 122b, 122c, 122d, may be arranged.

Referring to FIG. 23, in order to simplify the process of deriving the resistance of the dummy light-emitting element ED to be measured during the measurement process, the loopback wire LBL and the pad connection wire PAL may be made equal to have the same intrinsic resistance value relative to the dummy light-emitting element, and the cross-sectional area and length thereof may all be made equal to each other during the measurement process (LT0=LB0, LT1=LB1, LT2=LB2, LT3=LB3, LT4=LB4). For example, the loopback wire LBL may include the first connection wire 121 and the first electrode CE1, and the pad connection wire PAL may include the first connection wire 121 and the first electrode CE1. The wires 121a, 121b, 121c, and 121d included in the first connection wire 121 that is included in the loopback wire LBL may vary depending on the embodiment. The wire 121a, 121b, 121c, and 121d included in the first connection wire 121 that is included in the pad connection wire PAL may vary depending on the embodiment. As described above, instead of the wires 121a, 121b, 121c, and 121d included in the first connection wire 121 as shown, the wires 122a, 122b, 122c, and 122d included in the corresponding second connection wire 122 may be arranged. Even when the pad connection wire PAL includes the second connection wire, the wires included in the second connection wire may vary depending on the embodiment. Since the first electrode CE1 and the pad electrode PE correspond to each other, if either the pad connection wire PAL or the loopback wire LBL includes at least one of the first electrode CE1 and the pad electrode PE, the intrinsic resistances of the pad connection wire PAL and the loopback wire LBL may be matched.

In an embodiment, a probe PROBE may be placed on each of the pad connection wire PAL and the loopback wire LBL to measure resistance thereof. The probes PROBE having the same hatchings may be in contact with each of the wires PAL and LBL at the same time.

The length LB0 of the first-first connection wire 121a of the loopback wire LBL may be equal to the length LT0 of the first-first connection wire 121a of the pad connection wire PAL. The length LB1 of the first-second connection wire 121b of the loopback wire LBL may be equal to the length LT1 of the first-second connection wire 121b of the pad connection wire PAL. The length LB2 of the first-third connection wire 121c of the loopback wire LBL may be equal to the length LT2 of the first-third connection wire 121c of the pad connection wire PAL. The length LB3 of the first-fourth connection wire 121d of the loopback wire LBL may be equal to the length LT3 of the first-fourth connection wire 121d of the pad connection wire PAL. The length LB4 of the first electrode CE1 of the loopback wire LBL may be equal to the length LT4 of the first electrode CE1 of the pad connection wire PAL.

For example, because the length equality embodiment is only necessary “during the measurement process,” the display apparatus finally produced may not incorporate the length equality feature. Therefore, the length of the pad connection wire PAL may be different from the length of the loopback wire LBL in the display apparatus finally produced and.

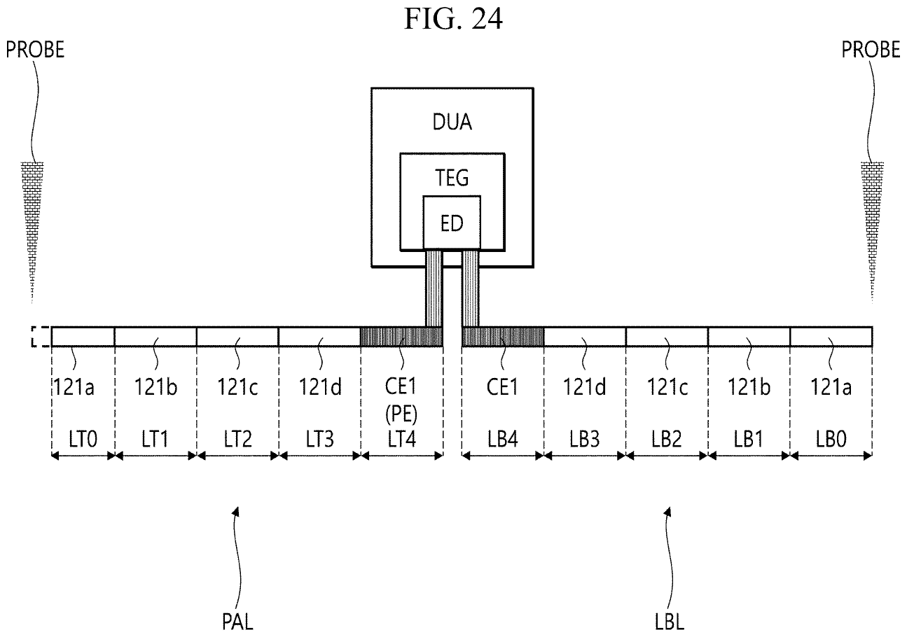

Referring to FIG. 24, after the measurement process, at least a portion of the pad connection wire PAL may be removed (as indicated by a dashed line in figure). Embodiments may vary depending on which connection wire the pad connection wire PAL includes, for example, at least a portion of the first-first connection wire 121a may be removed. In an embodiment, the length LB0 of the first-first connection wire 121a of the loopback wire LBL may be different from the length LT0 of the first-first connection wire 121a of the pad connection wire PAL. For example, the length LB0 of the first-first connection wire 121a of the loopback wire LBL may be greater than the length LT0 of the first-first connection wire 121a of the pad connection wire PAL (LT0<LB0). However, the present disclosure is not limited thereto, and the length LB0 of the first-first connection wire 121a of the loopback wire LBL and the length LT0 of the first-first connection wire 121a of the pad connection wire PAL may vary depending on the post-processing in the manufacturing process. For example, the length LB0 of the first-first connection wire 121a of the loopback wire LBL may be less than the length LT0 of the first-first connection wire 121a of the pad connection wire PAL. In one embodiment, the length LB1 of the first-second connection wire 121b of the loopback wire LBL may be equal to the length LT1 of the first-second connection wire 121b of the pad connection wire PAL. The length LB2 of the first-third connection wire 121c of the loopback wire LBL may be equal to the length LT2 of the first-third connection wire 121c of the pad connection wire PAL. The length LB3 of the first-fourth connection wire 121d of the loopback wire LBL may be equal to the length LT3 of the first-fourth connection wire 121d of the pad connection wire PAL. The length LB4 of the first electrode CE1 of the loopback wire LBL may be equal to the length LT4 of the first electrode CE1 of the pad connection wire PAL (LT0<LB0, LT1=LB1, LT2=LB2, LT3=LB3, LT4=LB4).

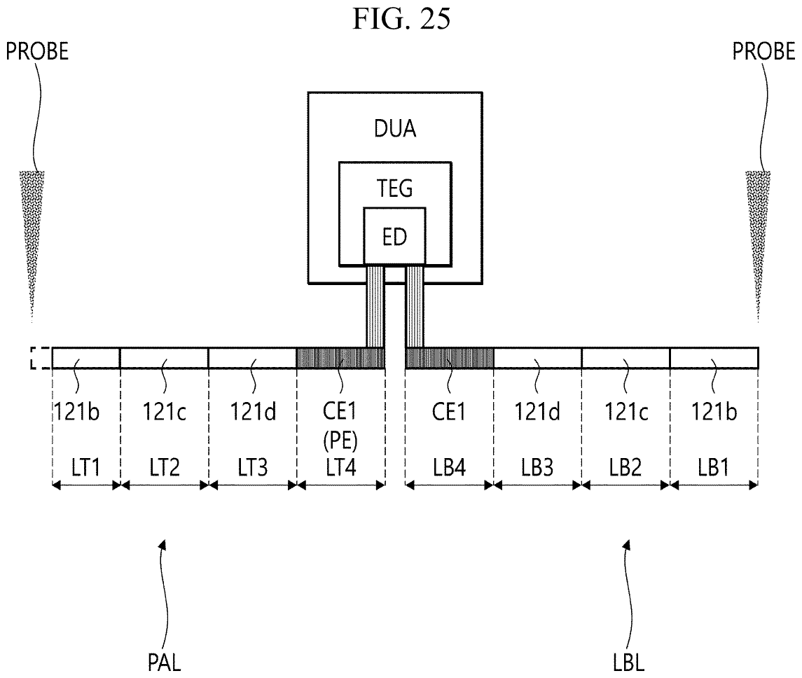

Referring to FIG. 25, after the measurement process, at least a portion of the first-second connection wire 121b may be removed (as indicated by a dashed line in figure). In one embodiment, the length LB1 of the first-second connection wire 121b of the loopback wire LBL may be different from the length LT1 of the first-second connection wire 121b of the pad connection wire PAL. For example, the length LB1 of the first-second connection wire 121b of the loopback wire LBL may be greater than the length LT1 of the first-second connection wire 121b of the pad connection wire PAL. However, it is not limited thereto, and the length LB1 of the first-second connection wire 121b of the loopback wire LBL and the length LT1 of the first-second connection wire 121b of the pad connection wire PAL may vary depending on the post-processing in the manufacturing process. For example, the length LB1 of the first-second connection wire 121b of the loopback wire LBL may be less than the length LT1 of the first-second connection wire 121b of the pad connection wire PAL. In one embodiment, the length LB2 of the first-third connection wire 121c of the loopback wire LBL may be equal to the length LT2 of the first-third connection wire 121c of the pad connection wire PAL. The length LB3 of the first-fourth connection wire 121d of the loopback wire LBL may be equal to the length LT3 of the first-fourth connection wire 121d of the pad connection wire PAL. The length LB4 of the first electrode CE1 of the loopback wire LBL may be equal to the length LT4 of the first electrode CE1 of the pad connection wire PAL (LT1<LB1, LT2=LB2, LT3=LB3, LT4=LB4).

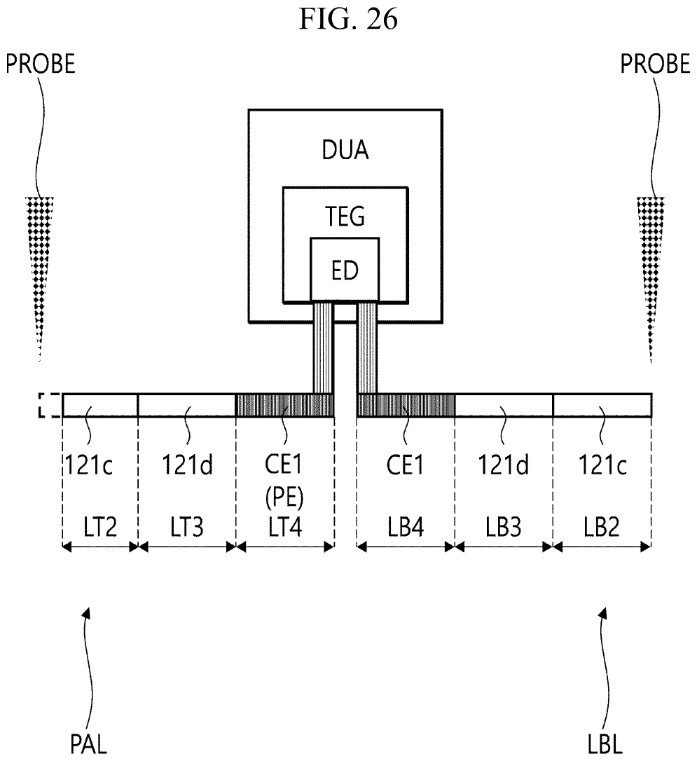

Referring to FIG. 26, after the measurement process, at least a portion of the first-third connection wire 121c may be removed (as indicated by a dashed line in figure). In one embodiment, the length LB2 of the first-third connection wire 121c of the loopback wire LBL may be different from the length LT2 of the first-third connection wire 121c of the pad connection wire PAL. For example, the length LB2 of the first-third connection wire 121c of the loopback wire LBL may be greater than the length LT2 of the first-third connection wire 121c of the pad connection wire PAL. However, it is not limited thereto, and may depend on post-processing in the manufacturing process. For example, the length LB2 of the first-third connection wire 121c of the loopback wire LBL may be less than the length LT2 of the first-third connection wire 121c of the pad connection wire PAL. In one embodiment, the length LB3 of the first-fourth connection wire 121d of the loopback wire LBL may be equal to the length LT3 of the first-fourth connection wire 121d of the pad connection wire PAL. The length LB4 of the first electrode CE1 of the loopback wire LBL may be equal to the length LT4 of the first electrode CE1 of the pad connection wire PAL (LT2<LB2, LT3=LB3, LT4=LB4).

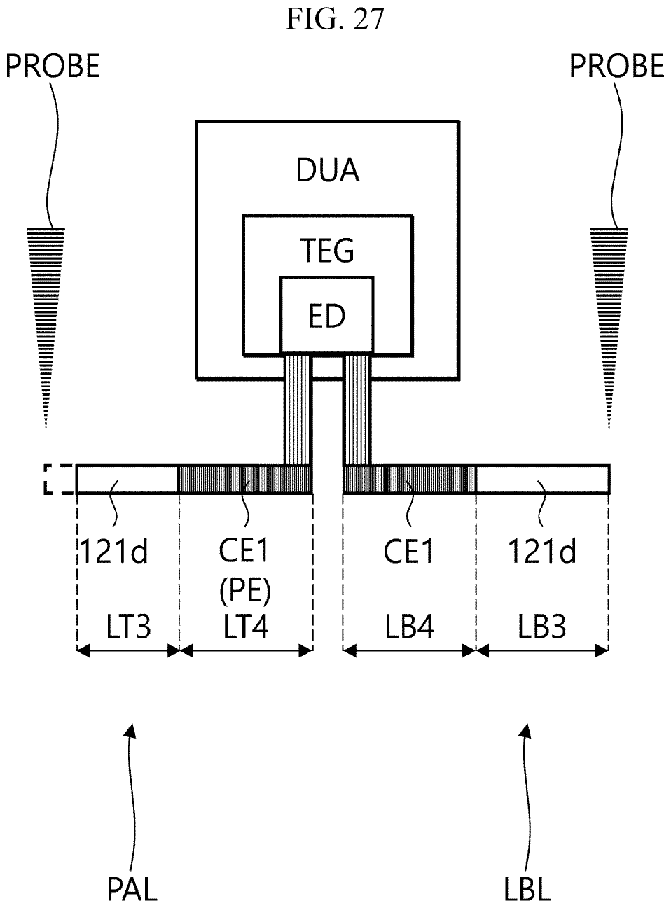

Referring to FIG. 27, after the measurement process, at least a portion of the first-fourth connection wire 121d may be removed (as indicated by a dashed line in figure). In one embodiment, the length LB3 of the first-fourth connection wire 121d of the loopback wire LBL may be different from the length LT3 of the first-fourth connection wire 121d of the pad connection wire PAL. For example, the length LB3 of the first-fourth connection wire 121d of the loopback wire LBL may be greater than the length LT3 of the first-fourth connection wire 121d of the pad connection wire PAL. However, it is not limited thereto, and may depend on post-processing in the manufacturing process. For example, the length LB3 of the first-fourth connection wire 121d of the loopback wire LBL may be less than the length LT3 of the first-fourth connection wire 121d of the pad connection wire PAL. In one embodiment, the length LB4 of the first electrode CE1 of the loopback wire LBL may be equal to the length LT4 of the first electrode CEL of the pad connection wire PAL (LT3<LB3, LT4=LB4).

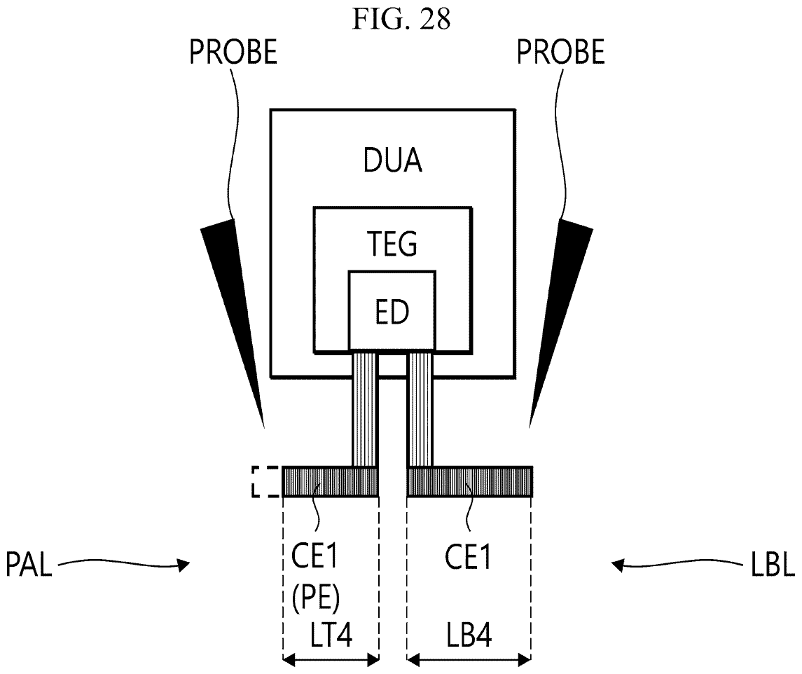

Referring to FIG. 28, after the measurement process, at least a portion of the first electrode CE1 may be removed (as indicated by a dashed line in figure). In one embodiment, the length LB4 of the first electrode CE1 of the loopback wire LBL may be different from the length LT4 of the first electrode CE1 of the pad-attached wire PAL. For example, the length LB4 of the first electrode CE1 of the loopback wire LBL may be greater than the length LT4 of the first electrode CE1 of the pad connection wire PAL. However, it is not limited thereto, and may depend on post-processing in the manufacturing process. For example, the length LB4 of the first electrode CE1 of the loopback wire LBL may be less than the length LT4 of the first electrode CE1 of the pad connection wire PAL (LT4<LB4).

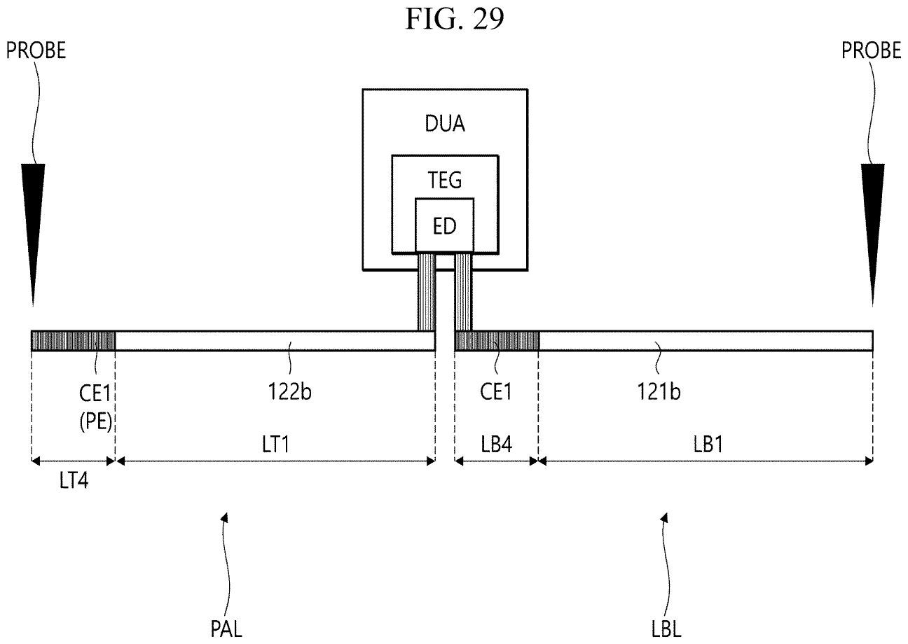

Referring to FIG. 29, in an embodiment, the pad connection wire PAL may include the second connection wire 122 and first electrodes CE1 (PE). The loopback wire LBL may include the first connection wire 121 and the first electrode CE1.

In the display apparatus according to an embodiment of the present disclosure, the length of the first electrode CE1 (PE) of the pad connection wire PAL during the measurement process may be equal to the length of the first electrode CE1 of the loopback wire LBL. During the measurement process, the length LT1 of the second-second connection wire 122b of the pad connection wire PAL may be equal to the length LB1 of the first-second connection wire 121b of the loopback wire LBL. In an embodiment, the length LB4 of the first electrode CE1 of the loopback wire LBL may be equal to the length LT4 of the first electrode CE1 (PE) of the pad connection wire PAL (LT1=LB1, LT4=LB4). Thus, the resistance of the dummy light-emitting element ED may be easily extracted.

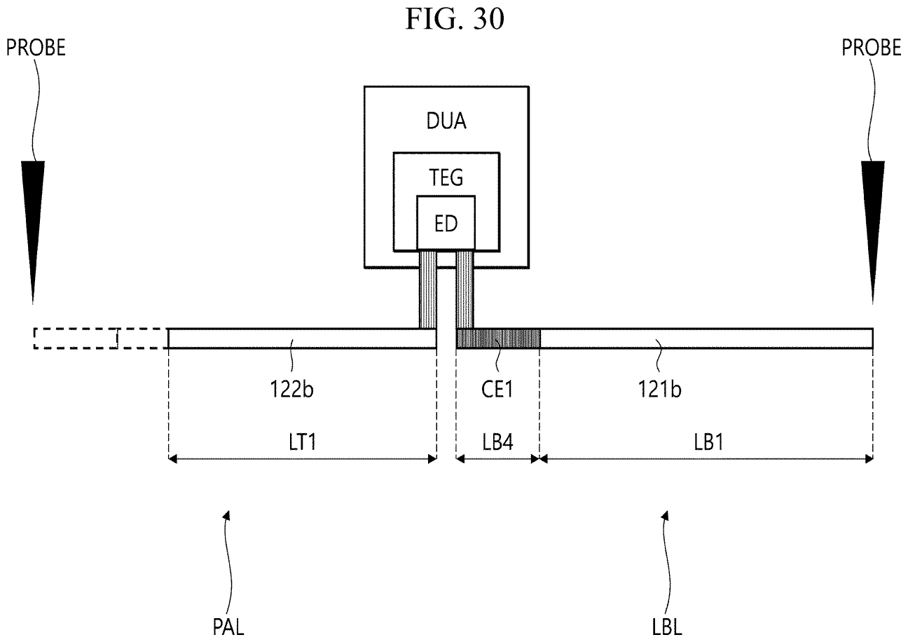

Referring to FIG. 30, after the measurement process, at least a portion of the pad connection wire PAL is removed (as indicated by a dashed line in figure), so that the length LT1 of the pad connection wire PAL may be different from the length (LB1+LB4) of the loopback wire LBL. For example, the length LT1 of the pad connection wire PAL may be less than the length (LB1+LB4) of the loopback wire LBL, but embodiments of the present disclosure are not limited thereto (LT1<LB1+LB4).

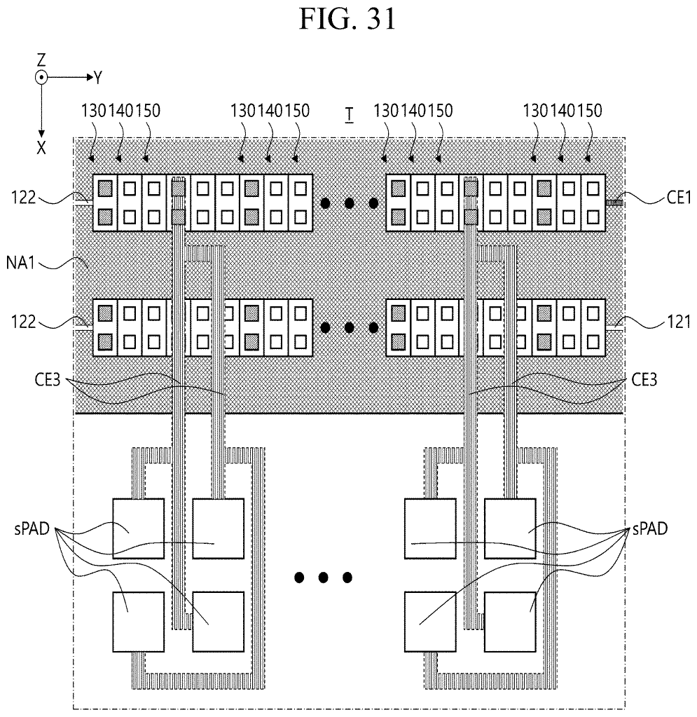

FIGS. 31 to 35 are plan views illustrating the display apparatus according to an embodiment of the present disclosure. FIGS. 31 to 34 are partially enlarged views illustrating an enlarged portion T of FIG. 18.

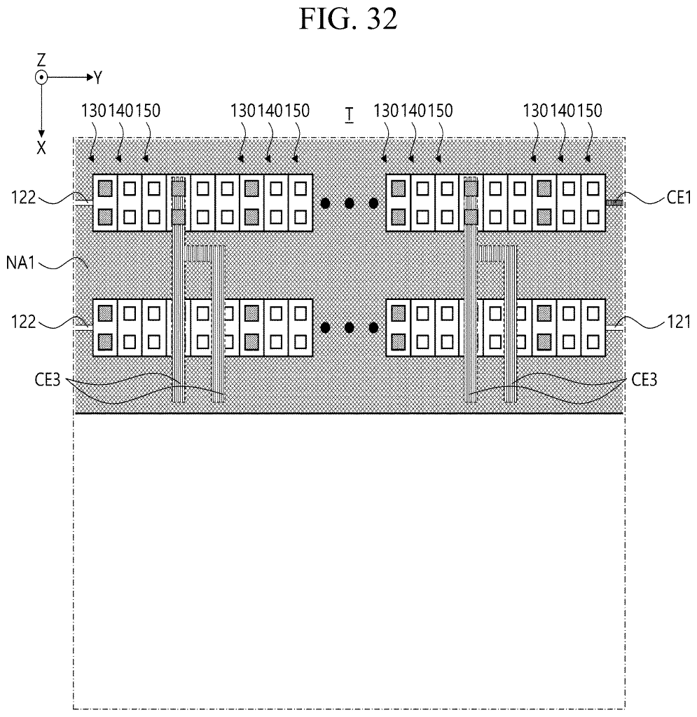

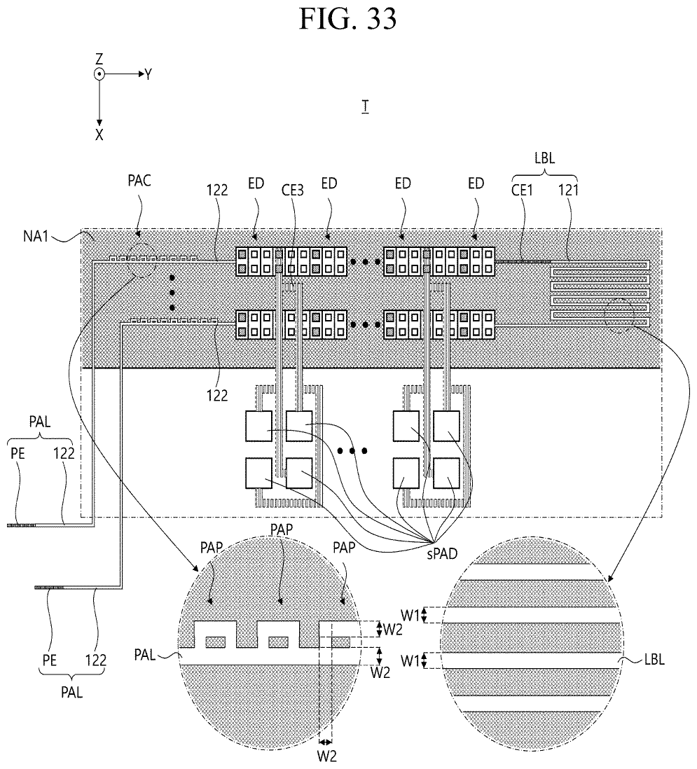

Referring to FIGS. 31 and 32, the separate pad sPAD may be connected during the measurement process and the separate pad may be removed after the measurement process. The third electrode CE3 may be arranged on the dummy light-emitting element ED and may supply the cathode voltage to the dummy light-emitting element ED during the measurement process. The third electrode CE3 may be connected to the separate pad sPAD. For example, FIGS. 31 and 33 are diagrams illustrating a process during the measurement process, and FIGS. 32, 34, and 35 are diagrams illustrating a process after the measurement process.

Referring to FIGS. 33 to 35, the loopback wire LBL may include the first electrode CE1 and the first connection wire 121. The first connection line 121 may be longer in length than the first electrode CE1 (LB1>LB4).

The pad connection wire PAL may include the pad electrode PE and the second connection wire 122. The second connection wire 122 may be shorter in length than the first connection wire 121. The second connection wire 122 may be formed to correspond to the first connection wire 121. The intrinsic resistance of the second connection wire 122 may be equal to the intrinsic resistance of the first connection wire 121.

The second connection wire 122 may include an auxiliary wire PAC. The auxiliary wire PAC can make the length of the loopback wire LBL equal to the length of the pad connection wire PAL during the measurement process to simplify the process of deriving the physical property of the dummy light-emitting element ED after the measurement process. The auxiliary wire PAC may be shorter in length than the loopback cabling LBL. For example, the auxiliary wire PAC may be shorter in length than the first connection wire 121. The auxiliary wire PAC may have a protrusion portion PAP. For example, the protrusion portion PAP may make the length of the loopback wire LBL and the pad connection wire PAL equal during the measurement process. The protrusion portion PAP may be connected to the second connection wire 122.

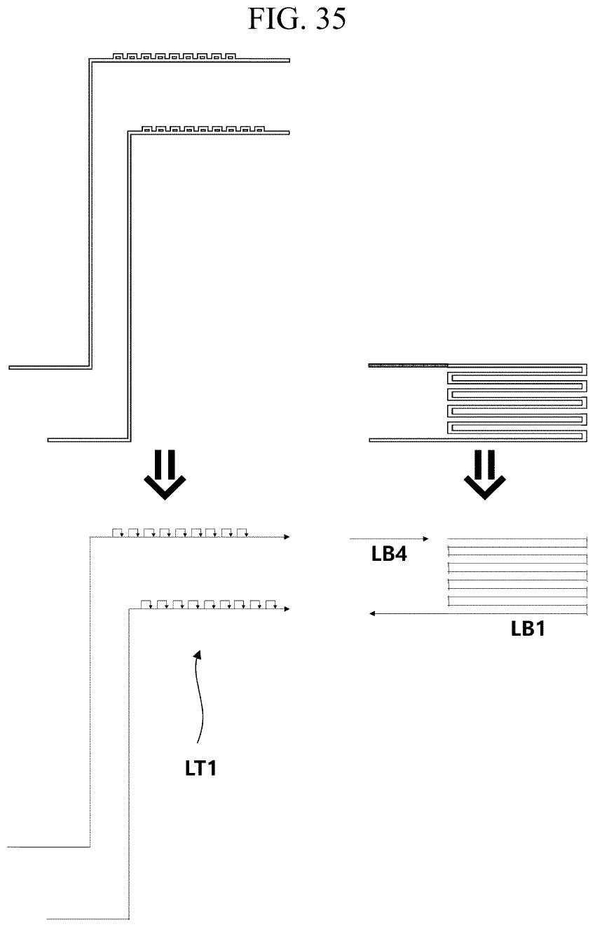

During the measurement process and after the measurement process, the first electrode CE1 of the loopback wire LBL may have a certain length LB4 (see FIG. 35) and width W1. The first connection wire 121 may have a certain length LB1 (see FIG. 35) and width W1. Therefore, the loopback wire LBL may have a certain length (LB1+LB4).

Referring to FIG. 33, during the measurement process, the pad electrode PE of the pad connection wire PAL may have a certain length and width W2. The second connection wire 122 may have a certain length and width W2. The width W2 of the pad connection wire PAL may be equal to the width W1 of the loopback wire LBL. The thickness of the pad connection wire PAL (e.g., the length of the wire in the Z-axis direction) may be equal to the thickness of the loopback wire LBL. Also, the total length of the pad electrode PE during the measurement process may be equal to the length of the first electrode CE of the loopback wire LBL. During the measurement process, the length of the first connection wire 121 may be equal to the length of the second connection wire 122. During the measurement process, the cross-sectional area of the pad connection wire PAL may be equal to the cross-sectional area of the loopback wire LBL. In this way, by making the resistance of the loopback wire LBL and the pad connection wire PAL equal, the display apparatus according to an embodiment of the present disclosure may simplify the calculation process related to the resistance measurement of the dummy light-emitting element ED.

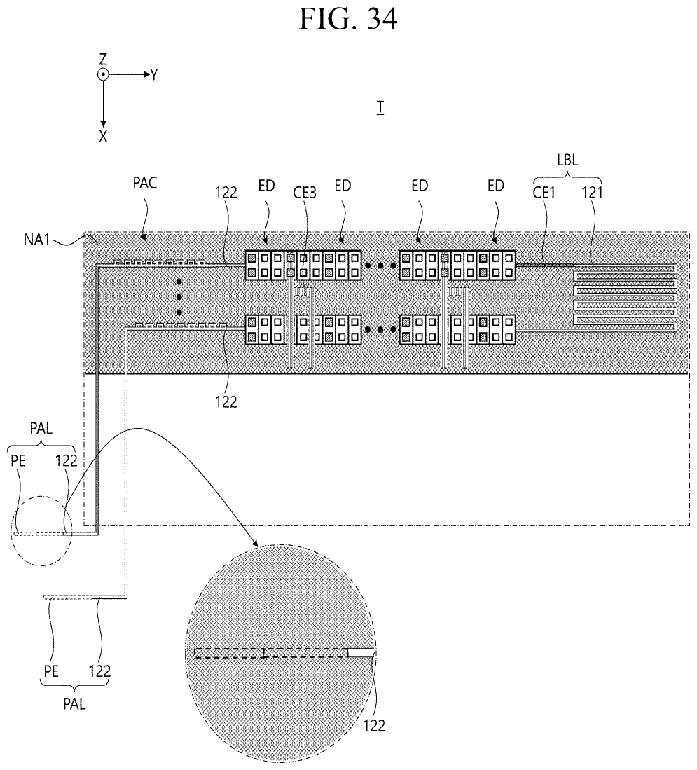

Referring to FIGS. 34 and 35, after the measurement process, at least a portion of the second connection wire 122 and the pad electrode PE may be removed (as indicated by the dashed lines in figures). Thus, after the measurement process, the second connection wire 122 may have a certain length LT1. The length LT1 of the second connection wire 122 may be shorter than the length LB1 of the first connection wire 121. The length LT1 of the second connection wire 122 may be less than the sum (LB1+LB4) of the length LB4 of the first electrode CE1 and the length LB1 of the first connection wire 121.

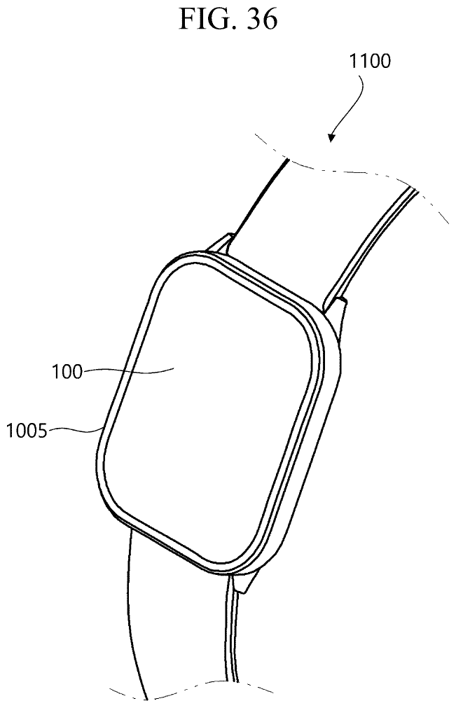

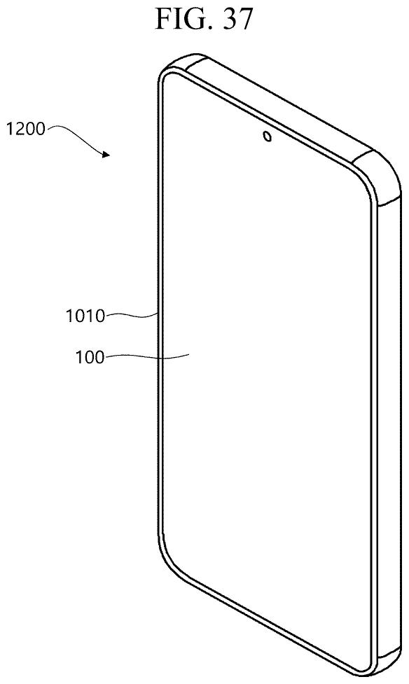

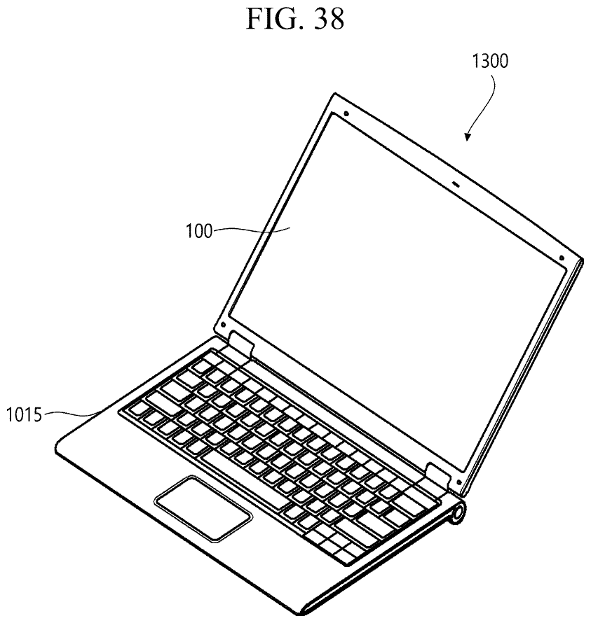

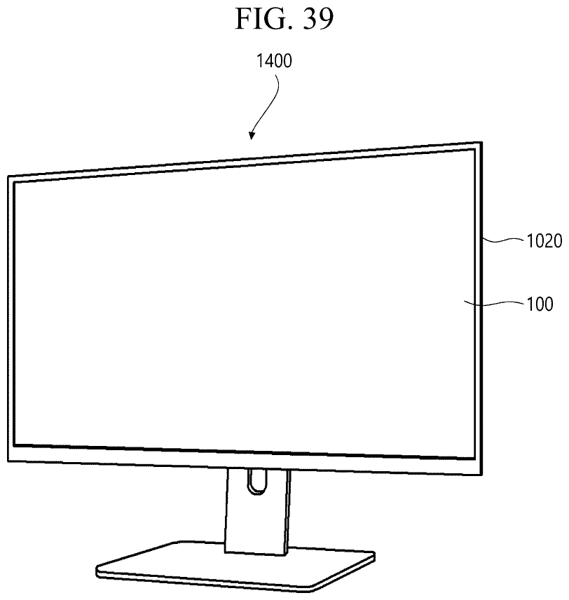

FIGS. 36 to 39 are diagrams illustrating an apparatus to which the display apparatus according to embodiments of the present disclosure is applied.

Referring to FIGS. 36 to 39, the display apparatus 1000 according to embodiments of the present disclosure may be included in a variety of devices or electronics. For example, various electronic devices may include a wearable device 1100, a mobile device 1200, a laptop 1300, and a monitor or television (TV) 1400, but embodiments of the present disclosure are not limited thereto.

The wearable device 1100, the mobile device 1200, the laptop computer 1300, and the monitor or TV 1400 may include their respective case parts 1005, 1010, 1015, and 1020, and the display panel 100 and the display apparatus 1000 according to the embodiments described above.

The display apparatus according to an embodiment of the present disclosure may include a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation, an in-vehicle display apparatus, an in-theater display apparatus, a television, a wallpaper device, a signage device, a gaming device, a laptop, a monitor, a camera, a camcorder, and a main board of a consumer electronics device.

The display apparatus according to various embodiments of the present disclosure may be described as follows.

A display apparatus according to various embodiments of the present disclosure may include a substrate; a display area, and a non-display area outside the display area; a loopback wire located in the non-display area; and a pad connection wire located in the non-display area and having a length that is different from a length of the loopback wire.

According to various embodiments of the present disclosure, the display apparatus may further include: a dummy light-emitting element located in the non-display area and arranged on a first electrode of the loopback wire, and a third electrode arranged on the dummy light-emitting element, wherein the loopback wire includes the first electrode.

According to various embodiments of the present disclosure, the third electrode may supply a cathode voltage.

According to various embodiments of the present disclosure, the loopback wire may further include: a first connection wire having a length greater than a length of the first electrode of the loopback wire.

According to various embodiments of the present disclosure, the pad connection wire includes a second connection wire having a length shorter than the length of the first connection wire of the loopback wire.

According to various embodiments of the present disclosure, the length of the second connection wire is less than a sum of the length of the first electrode and the length of the first connection wire of the loopback wire.

According to various embodiments of the present disclosure, the second connection wire may include an auxiliary wire that is shorter in length than the loopback wire.

According to various embodiments of the present disclosure, the auxiliary wire may include a protrusion portion connected to the second connection wire.

According to various embodiments of the present disclosure, a cross-sectional area of the loopback wire may be same as a cross-sectional area of the pad connection wire.

According to various embodiments of the present disclosure, the loopback wire may include a first connection wire. The pad connection wire may include a second connection wire. An intrinsic resistance of the first connection wire may be equal to an intrinsic resistance of the second connection wire.

According to various embodiments of the present disclosure, the display apparatus may further include: a pixel driving circuit located in the display area, including a plurality of pixel circuits and a plurality of light-emitting elements driven by the pixel driving circuit.

According to various embodiments of the present disclosure, the plurality of light-emitting elements may be inorganic light-emitting elements.

According to various embodiments of the present disclosure, the plurality of light-emitting elements nay have a vertical structure.

According to various embodiments of the present disclosure, the display apparatus may further include: an optical layer locate within the display area and placed in the plurality of light-emitting elements.

According to various embodiments of the present disclosure, the display apparatus may further include: a passivation layer arranged between the pixel driving circuit and the plurality of light-emitting elements.

According to various embodiments of the present disclosure, the display apparatus may further include: a plurality of banks arranged between the pixel driving circuit and the passivation layer.

According to various embodiments of the present disclosure, the display apparatus may further include: a pattern layer arranged between the plurality of banks and the plurality of light-emitting elements. The passivation layer may include a hole exposing the pattern layer.

According to various embodiments of the present disclosure, the display apparatus may further include: a first electrode arranged between the plurality of banks and the patterned layer.

According to various embodiments of the present disclosure, the optical layer may include a first optical layer arranged between a plurality of sub-pixels, a second optical layer arranged on the first optical layer, and a third optical layer arranged between a plurality of pixels.

According to various embodiments of the present disclosure, the display apparatus may further include: a second electrode arranged on the first optical layer.

A display apparatus according to various embodiments of the present disclosure may include: a substrate; a display area and a non-display area outside the display area; a first electrode placed in each of the display area and the non-display area, and a light-emitting element arranged on the first electrode; a second electrode located in the display area and arranged on the light-emitting element; and a third electrode located in the non-display area and arranged on a dummy light-emitting element, a loopback wire connected to the light-emitting dummy element, and a pad connection wire connected to the light-emitting dummy element.

According to various embodiments of the present disclosure, the light-emitting element includes: an anode electrode; a first semiconductor layer arranged on the anode electrode; an active layer arranged on the first semiconductor layer; a second semiconductor layer arranged on the active layer; and a cathode electrode arranged on the second semiconductor layer.

According to various embodiments of the present disclosure, the light-emitting element has a vertical structure.

According to various embodiments of the present disclosure, the display apparatus may further include: a first electrode below the light-emitting element and configured to connect to the anode electrode; and a pattern layer between the first electrode and the anode electrode. The first electrode and the anode electrode are electrically connected through a eutectic junction by the pattern layer.

According to various embodiments of the present disclosure, the length of the loopback wire may be different from the length of the pad connection wire.

Although the embodiments of the present invention have been described in more detail with reference to the accompanying drawings, the present invention is not necessarily limited to such embodiments, and may be variously modified within the scope thereof without departing from the technical spirit of the present invention.

Accordingly, the embodiments disclosed herein are provided for illustrative purposes and are not intended to limit the technical concept of the present invention, and the scope of the technical concept of the present invention is not limited to these embodiments.

Therefore, it should be understood that the embodiments described above are illustrative in all aspects and are not intended to be limiting.

The scope of protection of the present invention should be construed on the basis of the following claims, and all technical concepts within the equivalent scope thereof should be construed as falling within the scope of the present invention.

What is claimed is:

1. A display apparatus, comprising:
a substrate;
a display area, and a non-display area outside the display area;
a loopback wire located in the non-display area; and
a pad connection wire located in the non-display area, wherein the pad connection wire has a length that is different from a length of the loopback wire.

2. The display apparatus of claim 1, further comprising:
a dummy light-emitting element located in the non-display area and arranged on a first electrode of the loopback wire; and
a third electrode arranged on the dummy light-emitting element and configured to supply a cathode voltage,
wherein the loopback wire includes the first electrode.

3. The display apparatus of claim 2, wherein the loopback wire further includes a first connection wire having a length greater than a length of the first electrode of the loopback wire.

4. The display apparatus of claim 3, wherein the pad connection wire includes a second connection wire having a length shorter than the length of the first connection wire of the loopback wire.

5. The display apparatus of claim 4, wherein the length of the second connection wire is less than a sum of the length of the first electrode and the length of the first connection wire of the loopback wire.

6. The display apparatus of claim 4, wherein the second connection wire includes an auxiliary wire having a length shorter than the length of the loopback wire.

7. The display apparatus of claim 6, wherein the auxiliary wire includes a protrusion portion connected to the second connection wire.

8. The display apparatus of claim 1, wherein a cross-sectional area of the loopback wire is same as a cross-sectional area of the pad connection wire.

9. The display apparatus of claim 1, wherein the loopback wire includes a first connection wire,
wherein the pad connection wire includes a second connection wire, and
wherein an intrinsic resistance of the first connection wire is equal to an intrinsic resistance of the second connection wire.

10. The display apparatus of claim 1, further comprising: a pixel driving circuit located in the display area, the pixel driving circuit including a plurality of pixel circuits and a plurality of light-emitting elements driven by the pixel driving circuit.

11. The display apparatus of claim 10, wherein the plurality of light-emitting elements are inorganic light-emitting elements, and
wherein the plurality of light-emitting elements have a vertical structure.

12. The display apparatus of claim 11, further comprising:
an optical layer located in the display area and placed in the plurality of light-emitting elements.

13. The display apparatus of claim 12, further comprising:
a passivation layer arranged between the pixel driving circuit and the plurality of light-emitting elements, and
a plurality of banks arranged between the pixel driving circuit and the passivation layer.

14. The display apparatus of claim 13, further comprising:
a pattern layer arranged between the plurality of banks and the plurality of light-emitting elements,
wherein the passivation layer includes a hole exposing the pattern layer.

15. The display apparatus of claim 14, further comprising:
a first electrode arranged between the plurality of banks and the pattern layer.

16. The display apparatus of claim 12, wherein the optical layer includes a first optical layer arranged between a plurality of sub-pixels, a second optical layer arranged on the first optical layer, and a third optical layer arranged between a plurality of pixels.

17. A display apparatus, comprising:
a substrate;
a display area and a non-display area outside the display area;
a first electrode placed in each of the display area and the non-display area, and a light-emitting element arranged on the first electrode;
a second electrode located in the display area and arranged on the light-emitting element; and
a third electrode located in the non-display area and arranged on a dummy light-emitting element, a loopback wire connected to the dummy light-emitting element, and a pad connection wire connected to the dummy light-emitting element.

18. The display apparatus of claim 17, wherein the light-emitting element includes:
an anode electrode;
a first semiconductor layer arranged on the anode electrode;
an active layer arranged on the first semiconductor layer;
a second semiconductor layer arranged on the active layer; and
a cathode electrode arranged on the second semiconductor layer, and
wherein the light-emitting element has a vertical structure.

19. The display apparatus of claim 18, further comprising a pattern layer between the first electrode and the anode electrode,
wherein the first electrode and the anode electrode are electrically connected through an eutectic junction by the pattern layer.

20. The display apparatus of claim 17, wherein a length of the loopback wire is different from a length of the pad connection wire.
